(19) United States
(12) Patent Application Publication
(10) Pub. No.: US 2022/0131375 A1
(43) Pub. Date: Apr. 28, 2022

(54) SYSTEM AND METHOD FOR ENERGY INFRASTRUCTURE AND GEOSPATIAL DATA VISUALIZATION, MANAGEMENT, AND ANALYSIS USING ENVIRONMENT SIMULATION AND VIRTUAL REALIZATION

(71) Applicant: Michael Andrew Davis, II, Lockhart, TX (US)

(72) Inventor: Michael Andrew Davis, II, Lockhart, TX (US)

(21) Appl. No.: 17/512,447

(22) Filed: Oct. 27, 2021

Related U.S. Application Data
(60) Provisional application No. 63/106,119, filed on Oct. 27, 2020.

(51) Int. Cl. H02J 3/00; H02J 3/34

(52) U.S. Cl. CPC H02J 3/003; H02J 3/34; H02J 3/004

(57) ABSTRACT

A method for managing an electric utility power grid including a utility power line route may include generating an infrastructure model including utility assets and image information; receiving power line imaging data collected on the route and including utility asset imaging data; receiving geospatial topological model information; and generating a navigable simulated virtual environment model including an integrated visualization of infrastructure model image information with geospatial topological model image information and power line imaging data. A trained classification algorithm categorizes the condition of utility assets on the route from virtual views.

### CROSS-REFERENCE TO RELATED APPLICATIONS

This application is related and claims priority to U.S. Provisional Application 63/106,119 filed Oct. 27, 2020 and titled “System and Method for Energy Infrastructure and Geospatial Data Visualization, Management, and Analysis Using Environment Simulation and Virtual Realization,” which is hereby incorporated by reference in entirety.

### FIELD OF THE INVENTION

The disclosure generally relates to systems, apparatus and methods for electrical power grid operation, maintenance, repair, resiliency, and post-storm recovery. More particularly, the disclosure relates to systems, apparatus, and methods for optimizing inspection of electrical power grid infrastructure.

### BACKGROUND OF THE INVENTION

In the context of electric utility power grid (“grid”) infrastructure for distribution of electricity, resiliency is the capability to maintain optimal grid performance during system disruptions and recover quickly from such system disruptions. Many external factors influence how utilities address the resiliency of the grid, including severe weather, cyberattacks, terrorism, theft, electromagnetic impulses, vandalism and supply chain disruptions. Weather remains the single greatest threat to the electric power grid, and the impacts caused by significant storms can be long-lasting and widespread.

When the grid is damaged due to significant storms, it is very costly for the utility operator to identify particular failure locations due to the vast size of electrical transmission and distribution circuits, which can span hundreds of miles. Pinpointing a failure in a circuit requires the expensive process of dispatching human teams to “walk the line” and physically inspect the circuit to identify damage.

The above-referenced problems are exemplified by damage to grid infrastructure in Texas caused by hurricane Harvey in 2017. Harvey made landfall on Aug. 26, 2017 on the southern coast of Texas. Over the next several days the storm battered the region, including Houston, with heavy rains, wind, and flooding. According to the National Hurricane Center (NHC), over 336,000 customers, or meters, serving millions of people, lost power during the storm. American Electric Power (AEP), for example, is one of the many transmission and distribution utilities (TDU) that services the state, representing about a million of the ten million meters in the state.

AEP reported about $415 million in costs to recover from Harvey-related damages to their transmission and distribution (T&D) infrastructure. Not well reported, however, is what these costs represent. Most of these costs were labor-related. This included the hourly time costs of the necessary skilled labor, the engineers, electricians, and linemen, as well as their lodging, travel, tools and equipment, repair trucks, and so on. In the midst of hurricane Harvey, AEP called in about 5,600 additional workers from all over the country, paid on contract, and had crews of personnel working around the clock in 14 to 16 hour shifts, to restore power and begin restoration efforts which would last months and years.

It is very difficult to inspect T&D infrastructure. Even when it is known that there is an outage in a certain region, for example a specific circuit is down, the cause of the outage may be concealed within miles of power line, potentially dozens if not hundreds of miles worth. Currently, the only practical way to locate damage is visually, by having teams of humans “walk the line” so to speak. This entails literally driving around, walking around, or in the case of Harvey even boating around, looking for damage.

While monitoring and control technology exist, such technology is expensive, rarely deployed, and not very useful in scenarios that involve physical damage or multiple points of damage to a widely distributed grid from a significant storm. If a circuit goes down, for example, a monitoring system might be able to direct repair personnel to the first point of failure. After the circuit is de-energized, however, monitoring equipment will go offline with the circuit. Bringing the circuit back online may require replacing many pieces of hardware, in multiple locations. Even advanced monitoring equipment will not locate, identify or inform the utility grid operator that these many pieces of hardware in multiple locations have failed or suffered damage and must be repaired or replaced.

Complicating the matter further, this is also the same for finding damage, and safety hazards, in the absence of an outage. After a storm, infrastructure needs to be inspected even if power is online. There are many potential scenarios. For example, distribution poles could be leaning while the attached conductors are live and still delivering power. Lines could be low or touching the ground. Infrastructure could have sustained damage and be on the verge of causing a system failure, and/or present immediate life health safety hazards. The only way for the utility company to know whether particular infrastructure is damaged and/or presents immediate hazards, is by inspecting all of the infrastructure in the service area subjected to the storm.

AEP alone has about 43,000 miles worth of distribution line in Texas. CenterPoint Energy, another TDU in Texas, has about 50,000 miles. Statewide there are hundreds of thousands of miles worth of distribution line. It is not feasible to visually inspect all of this infrastructure each time there is a severe weather event. Even when damage is known to exist due to an outage, the need to visually inspect to determine scope of such dramatically increases resiliency costs and time to recover to normal or optimal grid performance. There is a need for improved systems, apparatus and methods for electrical power grid inspection, resiliency and post-storm recovery.

### BRIEF SUMMARY OF THE INVENTION

The above-mentioned shortcomings, disadvantages and problems are addressed herein, as will be understood by those skilled in the art upon reading and studying the following specification. This summary is provided to introduce a selection of concepts in simplified form that are further described below in more detail in the Detailed Description. This summary is not intended to identify key or essential features of the claimed subject matter.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Light Detection and Ranging (“LIDAR” or “lidar”) systems are a mature technology that performs geospatial three-dimensional scans. Lidar systems include an active remote sensor of a laser pulse reflection that operates in the visible or near-visible part of the electromagnetic spectrum to obtain spatial measurements. Lidar technology is a portmanteau of light and conventional radar, used by scientists since the 1960s, with its first applications in meteorology for measuring clouds and pollution. The basic operation of lidar is that light pulses are transmitted, and then reflections are captured. The travel time, divided by speed of light, then determines distance. Lidar operates with a relatively short wavelength and enables collection of distance data at high resolution.

Current technology is, however, incapable of managing the volume of lidar data collected from flight vehicles flying along known power line routes, such as power line routes extending many miles. Extensive human and computing resources and time must be devoted to handling and post-processing of raw lidar data before reviewing can be performed. Reviewing post-processed lidar data is a further unduly tedious, manual process that requires skilled, trained personnel to perform vast amounts of review efforts requiring many hours. Existing visualization software is limited and can only process small portions of the lidar data at any time.

According to the present disclosure, flight vehicles may fly along known power line routes may quickly collect lidar scan data (“lidar data”) of grid infrastructure, and automated visualization of the collected lidar data may enable remote observation and inspection of the grid infrastructure in a virtual model system including geographic information and network topology information. In an embodiment, semi-automated inspection of the grid infrastructure may be performed by a computing device configured to perform an automated inspection algorithm and provide the inspection algorithm output to a visual display for viewing by a user. In an embodiment, fully automated inspection of the grid infrastructure may be performed by a computing device configured to perform such an automated inspection algorithm and provide an automated inspection classification with the inspection algorithm output. In an embodiment, an automated inspection algorithm may be a trained machine learning algorithm or artificial intelligence algorithm. Such machine learning algorithm or artificial intelligence algorithm may be trained, for example, by reference to a plurality of correlated lidar data sets and grid infrastructure.

Apparatus, systems, and methods of varying scope are described herein. These aspects are indicative of various non-limiting ways in which the disclosed subject matter may be utilized, all of which are intended to be within the scope of the disclosed subject matter. In addition to the aspects and advantages described in this summary, further aspects, features, and advantages will become apparent by reference to the associated drawings, detailed description, and claims.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

The novel features believed characteristic of the disclosed subject matter will be set forth in any claims that are filed later. The disclosed subject matter itself, however, as well as a preferred mode of use, further objectives, and advantages thereof, will best be understood by reference to the following detailed description of an illustrative embodiment when read in conjunction with the accompanying drawings, wherein:

FIG. 1 is a simplified view of a flow diagram illustrating a method for managing an electric utility power transmission and distribution grid, in an exemplary embodiment.

FIG. 2 is a simplified view of a block diagram illustrating a system for managing an electric utility power transmission and distribution grid, in an exemplary embodiment.

FIG. 3 is a simplified view of a modeled transmission system with a transmission tower leg selected.

FIG. 4 is a simplified view of a transformer selected in a circuit diagram in an embodiment.

FIG. 5 is a simplified view of a 2D one-line diagram of a power generation plant laid over ground.

FIG. 6 is a simplified, zoomed view of a 2D one-line diagram of a power generation plant laid over ground.

FIG. 7 is a simplified view of a 3D model of a power plant laid over 2D diagram of the same.

FIG. 8 is a simplified view (angled) of a 3D model of power plant laid over 2D diagram of the same.

FIG. 9 is a simplified view of a 2D one-line diagram drawn directly on 3D terrain with satellite imagery.

FIG. 10 is a simplified top-down view of a 2D one-line diagram drawn directly on 3D terrain with satellite imagery.

FIG. 11 is a simplified view of a modeled power block in an embodiment.

FIG. 12 is a simplified view of a real-life power block 1.

FIG. 13 is a simplified view of a real-life power block 2.

FIG. 14 is a simplified view of a modeled fuel pumping module in an embodiment.

FIG. 15 is a simplified view of a real-life fuel pumping module in an embodiment.

FIG. 16 is a simplified view of a modeled transformer in a virtual switchyard, in an embodiment.

FIG. 17 is a simplified view of a real-life transformer in a switchyard, in an embodiment.

FIG. 18 is a simplified view of a lattice tower on mountain top in an embodiment.

FIG. 19 is a simplified view of a modeled terrain with color heightmap.

FIG. 20 is a simplified view of a modeled terrain with satellite imagery (3D).

FIG. 21 is a simplified view of a modeled terrain with satellite imagery (2D).

FIG. 22 is a simplified view of a day and night lighting cycle.

FIG. 23 is a simplified view of lighting, modeling time of day in an embodiment.

FIG. 24 is a simplified view of a selected insulator.

FIG. 25 is a simplified view of insulator details and photos.

FIG. 26 is a simplified view of a valve selected.

FIG. 27 is a simplified view of a motor selected.

FIG. 28 is a simplified view of an example of asset data, analysis and user custody assignments in an embodiment.

FIG. 29 is a simplified view of an example of asset data, insulator details and photos in an embodiment.

FIG. 30 is a simplified view of a transformer asset data sheet, in an embodiment.

FIG. 31 is a simplified view of a virtualized control room for a power block in an embodiment.

FIG. 32 is a simplified view of control room entry, in an embodiment.

FIG. 33 is a simplified view of view of PLC cabinets and SCADA systems in an embodiment.

FIG. 34 is a simplified view of view of protective equipment in an embodiment.

FIG. 35 is a simplified enlarged view of a PLC cabinet in an embodiment.

FIG. 36 is a simplified view of a photo of a utility asset, in an embodiment.

FIG. 37 is a simplified view of photo editing in an embodiment.

FIG. 38 is a simplified view of a photo reference and calculations.

FIG. 39 is a simplified view of a lidar scan of a transmission line with terrain heat map.

FIG. 40 is a simplified view of a lidar point cloud density of tree and cell tower in an embodiment.

FIG. 41 is a simplified view of a helicopter equipped with lidar scanner in an embodiment.

FIG. 42 is a simplified view of a block diagram showing system architecture in an embodiment in an embodiment.

FIG. 43 is a simplified view of a modeled terrain with heat haze in an embodiment.

FIG. 44 is a simplified view of an elevation heatmap in an embodiment.

FIG. 45 is a simplified view of a modified elevation heatmap in an embodiment.

FIG. 46 is a simplified view of lidar data and terrain modeled together.

FIG. 47 is a simplified view of lidar data and terrain modeled together in long perspective, in an embodiment.

FIG. 48 is a simplified view of low voltage distribution poles below transmission lines in an embodiment.

FIG. 49 is a simplified view of a Google map view of a scene modeled in an embodiment.

FIG. 50 is a simplified view of image texture laid over terrain tile in an embodiment.

FIG. 51 is a simplified view of a map image provided in an embodiment.

FIG. 52 is a simplified view of mapping imagery streaming in an embodiment.

FIG. 53 is a simplified view of a misaligned map in an embodiment.

FIG. 54 is a simplified view of a correctly aligned map.

FIG. 55 is a simplified view of many tiles seen with mapping imagery.

FIG. 56 is a simplified view of lidar data, terrain, and mapping rendered together.

FIG. 57 is a simplified view of a neighboring transmission line running parallel seen in the mapping imagery in an embodiment.

FIG. 58 is a simplified view of a lattice tower in autocad in an embodiment.

FIG. 59 is a simplified view of a lattice tower in sketchup in an embodiment.

FIG. 60 is a simplified view of a first attempt at lattice tower rendered in an embodiment.

FIG. 61 is a simplified view of a tower asset modeled in an embodiment.

FIG. 62 is a simplified view of lidar data vs. modeled tower, front.

FIG. 63 is a simplified view of lidar data vs. modeled tower, top down, in an embodiment.

FIG. 64 is a simplified view of lidar data of a tower, top down, skewed.

FIG. 65 is a simplified view of an examining screenshot of lidar data with photoshop.

FIG. 66 is a simplified view of a 10 meter cube model vs lidar points at corners.

FIG. 67 is a simplified view of lidar points aligned with model, in an embodiment.

FIG. 68 is a simplified view of a catenary shape assumed by suspended power lines, in an embodiment.

FIG. 69 is a simplified view of a catenaries for different values, in an embodiment.

FIG. 70 is a simplified view of a plot of equation 13 in an embodiment.

FIG. 71 is a simplified view of a solving equation 13 in an embodiment.

FIG. 72 is a simplified view of a plots of bisection method finding root of equation 13.

FIG. 73 is a simplified view of a tracking 2d along a horizontal, ground plane, in an embodiment.

FIG. 74 is a simplified view of a catenary modeled in a virtual world in an embodiment.

FIG. 75 is a simplified view of a catenary modeled in virtual world, towers up hillside, in an embodiment.

FIG. 76 is a simplified view of fc2 lidar data of a tower 88 asset modeled in an embodiment.

FIG. 77 is a simplified view of fc2 lidar data visualization, seen at tower 88 location.

FIG. 78 is a simplified view of fc2 lidar data visualization seen at tower 88 location, all sources combined, in an embodiment.

FIG. 79 is a simplified view of an asset model vs. lidar tower height mismatch.

FIG. 80 is a simplified view of an asset model extended along negative vertical axis.

FIG. 81 is a simplified view of asset model vs. lidar tower height matching, in an embodiment.

FIG. 82 is a simplified view of asset model vs. lidar insulator height mismatch.

FIG. 83 is a simplified view of corrected insulator model in an embodiment.

FIG. 84 is a simplified view of a modeled catenary vs. lidar in an embodiment.

FIG. 85 is a simplified view of a modeled catenary vs. lidar, perspective #2 in an embodiment.

FIG. 86 is a simplified view of a mismatch between modeled catenary and lidar data.

FIG. 87 is a simplified view of fc2 lidar data of tower 88 seen from side, in an embodiment.

FIG. 88 is a simplified view of fc2 lidar data of tower 88 seen from above in an embodiment.

FIG. 89 is a simplified view of fc2 lidar data of tower 88 seen from front, in an embodiment.

FIG. 90 is a simplified view of an asset model vs fc2 lidar data for tower 87.

FIG. 91 is a simplified view of outer vs inner volume boxes in an embodiment.

FIG. 92 is a simplified view of inner volume boxes in an embodiment.

FIG. 93 is a simplified view of inner volume boxes around 34 m tower in an embodiment.

FIG. 94 is a simplified view of inner volume boxes around 23 m tower.

FIG. 95 is a simplified view of aspect volume box around crossarm.

FIG. 96 is a simplified view of aspect volume box around crossarm and phases.

FIG. 97 is a simplified view of aspect volume boxes around each phase.

FIG. 98 is a simplified view of a projection box around tower, seen at angle.

FIG. 99 is a simplified view of a projection box around tower, side axis.

FIG. 100 is a simplified view of a projection box around tower, front axis.

FIG. 101 is a simplified view of a projection box around tower, lidar and box hidden, in an embodiment.

FIG. 102 is a simplified view of a projection box around tower, seen at an angle, in an embodiment.

FIG. 103 is a simplified view of a projection box around tower, seen at angle.

FIG. 104 is a simplified view of a projection box around tower, seen at angle in an embodiment.

FIG. 105 is a simplified view of a volume box axis projections, phases, in an embodiment.

FIG. 106 is a simplified view of a volume box axis projections, phases, boxes hidden.

FIG. 107 is a simplified view of a volume box axis projections, crossarm, in an embodiment.

FIG. 108 is a simplified view of a volume box axis projections, crossarm, box hidden, in an embodiment.

FIG. 109 is a simplified view of a lidar projected 2d at 45 degrees rotated, in an embodiment.

FIG. 110 is a simplified view of a lidar ground points pre-segmentation (in foreground) in an embodiment.

FIG. 111 is a simplified view of a lidar ground points pre-segmentation, more prominent view in an embodiment.

FIG. 112 is a simplified view of a 2d segmentation by volume of interest, in an embodiment.

FIG. 113 is a simplified view of a 3d segmentation by volume of interest in an embodiment.

FIG. 114 is a simplified view of segmentation by volumes of interest in an embodiment.

FIG. 115 is a simplified view of voi acquisition in an embodiment.

FIG. 116 is a simplified view of voi acquisition, outer volume hidden in an embodiment.

FIG. 117 is a simplified view of voi acquisition, phase aspects in an embodiment.

FIG. 118 is a simplified view of voi acquisition, phase aspects, lidar hidden, in an embodiment.

FIG. 119 is a simplified view of an acquisition object in an embodiment.

FIG. 120 is a simplified view of an extraction object in an embodiment.

FIG. 121 is a simplified view of an incident plane rotation about normal vector (−91.5°).

FIG. 122 is a simplified view of a plot of extracted features for towers, in an embodiment.

FIG. 123 is a simplified view of a tower 3 vs. 4, projection along z axis.

FIG. 124 is a simplified view of a plot of select features, good vs. damaged (rotated) towers.

FIG. 125 is a simplified view of a linear separation.

FIG. 126 is a simplified view of a single layer perceptron in an embodiment.

FIG. 127 is a simplified view of a multi-layer perceptron in an embodiment.

FIG. 128 is a simplified view of an initial classification test (multilayer perceptron).

FIG. 129 is a simplified view of a point cloud selection and manipulation.

FIG. 130 is a simplified view of a point cloud selection and layer assignment in an embodiment.

FIG. 131 is a simplified view of a point selections from layers in an embodiment.

FIG. 132 is a simplified view of a tower bent by storm in an embodiment.

FIG. 133 is a simplified view of a tower arm bent by storm in an embodiment.

FIG. 134 is a simplified view of a deformation applied to selection, in an embodiment.

FIG. 135 is a simplified view of a cloud cloned by volume of interest in an embodiment.

FIG. 136 is a simplified view of a cross arm rotated to simulate damage in an embodiment.

FIG. 137 is a simplified view of a lean rotation applied to tower to simulate damage in an embodiment.

FIG. 138 is a simplified view of a cloned tower in an embodiment.

FIG. 139 is a simplified view of a noise applied to clone tower vs. original, in an embodiment.

FIG. 140 is a simplified view of a real-time data collection algorithm.

FIG. 141 is a simplified view of lidar data appearing during real-time simulation.

FIG. 142 is a simplified view of an acquisition volume appearing during real-time simulation.

FIG. 143 is a simplified view of model generation in an embodiment.

FIG. 144 is a simplified view of classifier training.

FIG. 145 is a simplified view of a breaking single phase of crossarm.

FIG. 146 is a simplified view of a broken crossarm damage detected by classifier, in an embodiment.

### DETAILED DESCRIPTION OF THE INVENTION

In this detailed description, reference is made to the accompanying drawings which form a part hereof, and in which is shown by way of illustration specific embodiments which may be practiced. Reference now should be made to the drawings, in which the same reference numbers are used throughout the different figures to designate the same components. These embodiments are described in sufficient detail to enable those skilled in the art to practice the embodiments and disclosure. It is to be understood that other embodiments may be utilized, and that logical, mechanical, electrical, and other changes may be made without departing from the scope of the embodiments and disclosure. In view of the foregoing, the following detailed description is not to be taken as limiting the scope of the embodiments or disclosure.

The terminology used herein is for the purpose of describing particular embodiments only and is not intended to be limiting. As used herein, the singular forms “a”, “an”, and “the” are intended to include the plural forms as well, unless the context clearly indicates otherwise. It will be further understood that the terms “comprises” and/or “comprising” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be appreciated that for simplicity and clarity of illustration, where considered appropriate, reference numerals may be repeated among the figures to indicate corresponding or analogous elements. In addition, numerous specific details are set forth in order to provide a thorough understanding of the implementations described herein. However, it will be understood by those of ordinary skill in the art that the implementations described herein may be practiced without these specific details. In other instances, well-known methods, procedures and components have not been described in detail so as not to obscure the implementations described herein. Also, the description is not to be considered as limiting the scope of the implementations described herein.

The detailed description set forth herein in connection with the appended drawings is intended as a description of exemplary embodiments in which the presently disclosed apparatus and system can be practiced. The term “exemplary” used throughout this description means “serving as an example, instance, or illustration,” and should not necessarily be construed as preferred or advantageous over other embodiments.

The following illustrates the principles of the invention. It will be appreciated that those skilled in the art will be able to devise various arrangements which, although not explicitly described or shown herein, embody the principles of the invention and may be included in the spirit and scope.

The text Understanding Virtual Reality (Second Edition), Sherman W. and Craig A. (Elsevier Inc. 2018) is incorporated by reference in entirety. The text Networked Graphics—Building Networked Games and Virtual Environments (First Edition), Steed A. and Oliveira M. F. (Morgan Kaufmann 2009) is incorporated by reference in entirety. The text Developing Virtual Reality Applications, Craig A., Sherman W. and Will J. (Elsevier 2009) is incorporated by reference in entirety. The text Electric Power Distribution Engineering (3^{rd} Edition), Gonen T. (CRC Press 2014) is incorporated by reference in entirety.

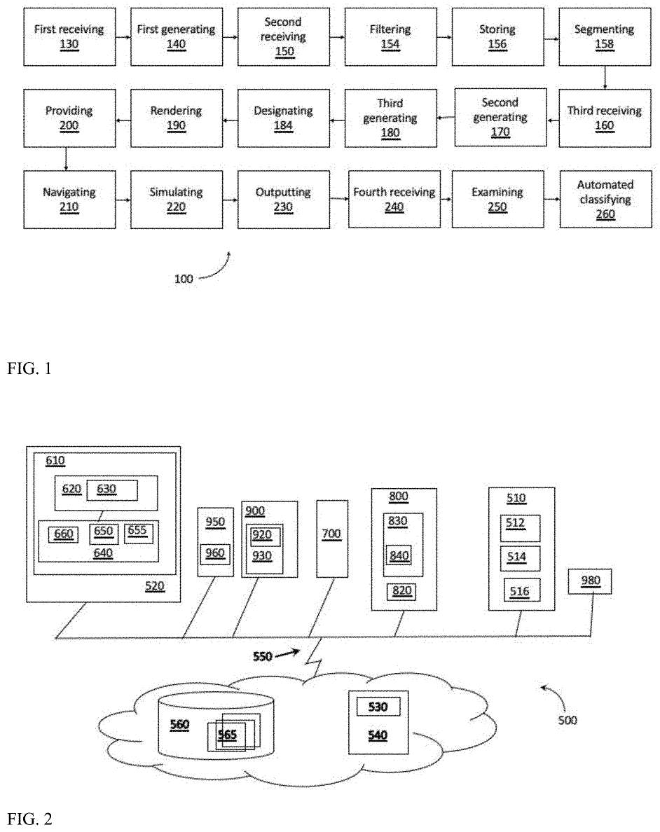

FIG. 1 is a simplified flow diagram illustrating a method 100 for managing an electric utility power transmission and distribution grid, in an exemplary embodiment. The grid may include a plurality of utility assets distributed on a utility power line route in a geographic area and may be substantially identical to grid 510 shown in FIG. 2 or may have any configuration suitable for transmission and distribution of electricity.

As shown in FIG. 1, method 100 may include first receiving 130, at a processor, infrastructure information of the grid. The grid includes a plurality of utility assets distributed on the utility power line route in the geographic area. The utility assets, for example, may include a generating station supplying electricity via step-up transformers to high voltage transmission lines strung between a plurality of transmission towers. The utility assets also may include a plurality of substations including step-down transformers to supply distribution assets. The distribution assets may include distribution substations supplying electricity to lower voltage distribution lines strung between a plurality of distribution poles to supply terminal distribution assets at end user facilities such as commercial facilities, businesses and residences.

As shown in FIG. 1, method 100 may include first generating 140, by a processor, an infrastructure model of the grid, from the infrastructure information. The infrastructure model may include utility asset data for the plurality of utility assets. In an embodiment, the utility asset data for the plurality of utility assets may be organized or grouped in a plurality of utility asset data objects, in relation to the plurality of utility assets. The infrastructure model may include asset classification data in relation to the plurality of utility assets. The infrastructure model may include infrastructure model image information, which may include utility asset image information. The infrastructure model also may include infrastructure three-dimensional structural information, which may include utility asset three-dimensional structural information. In an embodiment, the infrastructure model information may include geospatial information. The geospatial information, in an embodiment, may be global positioning system (GPS) coordinates.

As shown in FIG. 1, method 100 may include second receiving 150, at a processor, power line imaging data collected along the power line route. The power line imaging data may include utility asset imaging data collected in relation to the plurality of utility assets on the power line route. In an embodiment, the power line imaging data may be selected from the following: lidar data, telemetry data, photography data, and photogrammetry data. In an embodiment, the power line imaging data may include lidar data. In an embodiment, the power line imaging data may include lidar data and telemetry data. In an embodiment, the power line imaging data may include geospatial coordinate information for the collection location and attitude of the collector, which may include geographic positioning system (GPS) coordinates for the collection location. In an embodiment, the power line imaging data is a point cloud, which may be organized as a two-dimensional bitmap. In an embodiment, method 100 may include filtering 154, by a processor, the power line imaging data to reduce imaging data collected of the ground. In an embodiment, method 100 may include storing 156 the power line imaging data in a cloud database indexed by geospatial information. In an embodiment, the power line imaging data may be stored in such a cloud database indexed by geospatial information comprising global positioning system (GPS) coordinates. In an embodiment, the infrastructure model information and the power line imaging data may include geospatial information. The geospatial information, in an embodiment, may be global positioning system (GPS) coordinates. In an embodiment, method 100 may include segmenting 158, by a processor, the power line imaging data in relation to a plurality of asset volumes. Each of the plurality of asset volumes may be assigned at a respective geospatial location of a corresponding each of the plurality of utility assets.

As shown in FIG. 1, method 100 may include third receiving 160, at a processor, geospatial topological model information for the geographic area. The geospatial topological model information may include geospatial coordinate information, terrain data and elevation data. The geospatial topological model information may include geospatial topological model image information. In an embodiment, the geospatial topological model information may include geospatial coordinate information, which may be geographic positioning system (GPS) coordinates.

As shown in FIG. 1, method 100 may include second generating 170, by a processor, a geospatial topological model of the geographic area, from the geospatial topological information. The geospatial topological model may include geospatial coordinate information, terrain data and elevation data. The geospatial topological model may include geospatial topological model image information. In an embodiment, the geospatial topological model may include geospatial coordinate information, which may be geographic positioning system (GPS) coordinates. The GPS coordinates may relate to the geospatial topological model image information.

As shown in FIG. 1, method 100 may include third generating 180, by a processor of a virtual world platform, a navigable virtual environment, from the infrastructure information, power line imaging data, and geospatial topological information. The virtual environment may include an integrated model. The integrated model may include an integration of the infrastructure information, power line imaging data, and geospatial topological information data. The integrated model may include an integration of the infrastructure model, geospatial topological model, and power line imaging data. The integrated model may include integrated image information, including an integrated visualization of the infrastructure model image information with the geospatial topological model image information, and with the power line imaging data. Method 100 may include designating 184, by a processor, a plurality of entities in said virtual world platform, where each designated entity includes the power line imaging data. In an embodiment, each of the plurality of entities may correspond to a utility asset, a geospatial location of a utility asset, or both.

As shown in FIG. 1, method 100 may include rendering 190, by a processor, the navigable virtual environment including the integrated visualization. The integrated visualization may include the infrastructure model image information with the geospatial topological model image information, and with the power line imaging data.

As shown in FIG. 1, method 100 may include providing 200, by a processor, a virtual viewer in relation to the navigable virtual environment. The viewer may include a first-person point of view. The viewer may include, for the point of view, a virtual view on the utility power line route depicted in the navigable virtual environment. The integrated visualization may include the infrastructure model image information including utility asset image information for the plurality of utility assets, the geospatial topological model image information, and power line imaging data for the plurality of utility assets. The virtual view may include the integrated visualization depicted from a point of view of the viewer. The providing 200, in an embodiment, may include loading into a virtual world platform the geospatial topological model, infrastructure model, and a model comprising the power line image data.

As shown in FIG. 1, method 100 may include navigating 210, by a processor, the viewer in relation to the navigable virtual environment between a plurality of static points of view on the utility power line route. Each virtual view may be depicted from a different static point of view and/or attitude of the viewer in relation to the navigable virtual environment. The plurality of virtual views may include the integrated visualization including the infrastructure model image information, including utility asset image information for the plurality of utility assets, depicted from different points of view and/or attitudes of the viewer. It will be understood that navigating 210 may be independent of simulating movement, such as between different static points of view in relation to the navigable virtual environment, without simulation of time and movement between different static points of view in non-sequential order.

As shown in FIG. 1, method 100 may include simulating 220, by a processor, movement of the viewer in relation to the navigable virtual environment to provide simulated movement of the viewer in a simulated time series, or simulated time period, between a plurality of camera points of view and/or attitudes. Simulating 220 may provide simulated movement of the viewer in a corresponding simulated time series of a plurality of virtual views and/or attitudes on the utility power line route depicted in the navigable virtual environment. Simulating 220 thus may simulate movement of the viewer between a plurality of depicted points of view and/or attitudes, of the integrated visualization including the infrastructure model image information, and utility asset image information for the plurality of utility assets. The simulating 220 of movement may include a simulated time series of different views of the integrated visualization along the utility power line route, depicted from different points of view and/or attitudes of the viewer on the utility power line route depicted in the virtual environment.

As shown in FIG. 1, method 100 may include outputting 230, by a processor, the virtual view to a display. The virtual view depicted in the display may provide, to a human user, visual information sufficient for classification of the condition of utility assets as being in damaged condition or normal condition.

As shown in FIG. 1, method 100 may include fourth receiving 240, at a processor, the plurality of virtual views from the viewer in relation to the navigable virtual environment between a plurality of static points of view on the utility power line route. The plurality of virtual views may be provided by navigating 210 as described hereinabove.

As shown in FIG. 1, method 100 may include examining 250, by a processor, the plurality of virtual views to identify damage visible in the integrated visualization including the infrastructure model image information, and including the utility asset image information, for the plurality of utility assets on the utility power line route.

As shown in FIG. 1, method 100 may include automated classifying 260, by a processor, utility assets in the virtual view as being in normal condition or damaged condition. Automated classifying 260 may include the processor executing a trained classification algorithm in run-time mode to compare the collected power line imaging data to reference classification information for the plurality of utility assets in damaged condition and normal condition (i.e., undamaged, working condition). The trained classification algorithm may develop the reference classification information for damaged condition or normal condition of the plurality of utility assets, by operating in a training mode during a training period. The trained classification algorithm in training mode may receive a plurality of training datasets. The training datasets may include reference power line imaging data for a plurality of utility assets classified in known normal condition or damaged condition. In an embodiment, the trained classification algorithm in the training period may develop the reference classification information in relation to receiving the reference power line imaging data in a reference view of infrastructure including a utility asset, where the reference view is selected from: a virtual view, a real-world image such as a photograph, or both. In an embodiment, the training datasets may include reference power line imaging data for a plurality of utility assets classified in known normal condition or damaged condition, where the reference power line imaging data, itself, is simulated power line imaging data. Such simulated power line imaging data may be generated, to provide the reference power line imaging data, by simulating or modeling the collection of power line imaging data, such as lidar data, in relation to the known geometry of a utility asset, such as a transmission tower, and such simulation or model also may, or may not, reflect adjustment in relation to an assumed, simulated or modeled collection position of the power line imaging platform, which may be a lidar imaging system carried on a flight transport such as a helicopter. In an embodiment, automated classifying 260 may include a processor executing the trained classification algorithm to compare, for a virtual view of a utility asset, the power line imaging data and a corrected geometric model of the utility asset in normal condition.

In relation to the automated classifying 260, the integrated model may include first geographic location information having first resolution for the geospatial topological model, second geographic location information having second resolution for the infrastructure model in relation to the first geographic location information, and third geographic location information having third resolution for the power line imaging data in relation to at least one of the first geographic location information and the second geographic location information. In an embodiment, the first resolution, second resolution, and third resolution may be sufficient to enable automated classifying 260 of the utility assets, by a processor executing the trained classification algorithm with the virtual view of the utility asset image information, as being in normal condition or damaged condition by reference to the integrated model including the integrated visualization on the utility power line route.

In the automated classifying 260, in an embodiment, the first resolution, second resolution and third resolution may be sufficient to enable the automated classifying 260 of the utility assets, by a processor executing the trained classification algorithm with the virtual view of utility asset image information, as being in normal condition or damaged condition, by reference to the integrated model including the integrated visualization of utility asset image information, without receiving first-person storm damage field survey information for visual field assessment of condition of each of the plurality of utility assets on the power line route.

In an embodiment, the automated classifying 260 of the utility assets, by a processor executing the trained classification algorithm with the virtual view of utility asset image information, as being in normal condition or damaged condition by reference to the integrated model including the integrated visualization of utility asset image information, to provide a level of assessment precision substantially equal to first-person storm damage field survey information for visual field assessment of condition of each of the plurality of utility assets on the power line route.

In an embodiment, the automated classifying 260 of the utility assets, by a processor executing the trained classification algorithm with the virtual view of utility asset image information, as being in normal condition or damaged condition by reference to the integrated model providing a level of assessment precision sufficient to enable automated assignments of storm damage repair crews with service equipment and substantially identical replacement utility assets sufficient to restore normal service by restoring damaged infrastructure to substantially normal condition for the plurality of utility assets on the power line route to realize substantially equal recovery efficiency in comparison to manual assignments utilization enabled by first-person storm damage field survey information for visual field assessment of condition of each of the plurality of utility assets on the power line route.

In an embodiment, the automated classifying 260 of the utility assets, by a processor executing the trained classification algorithm with the virtual view of utility asset image information, as being in normal condition or damaged condition by reference to the integrated model providing information sufficient to enable efficient dispatching decisions, to assign field survey personnel to perform first-person storm damage field surveys including visual field assessments of condition of each of the plurality of utility assets on the power line route classified in an indeterminate condition by the trained classification algorithm with the virtual view of utility asset image information.

It will be understood that a non-transitory computer-accessible medium may have stored thereon computer-executable instructions for a method for managing an electric utility power grid, wherein, when a computer hardware arrangement executes the instructions, the computer hardware arrangement is configured to perform procedures comprising the method 100 (shown in FIG. 1).

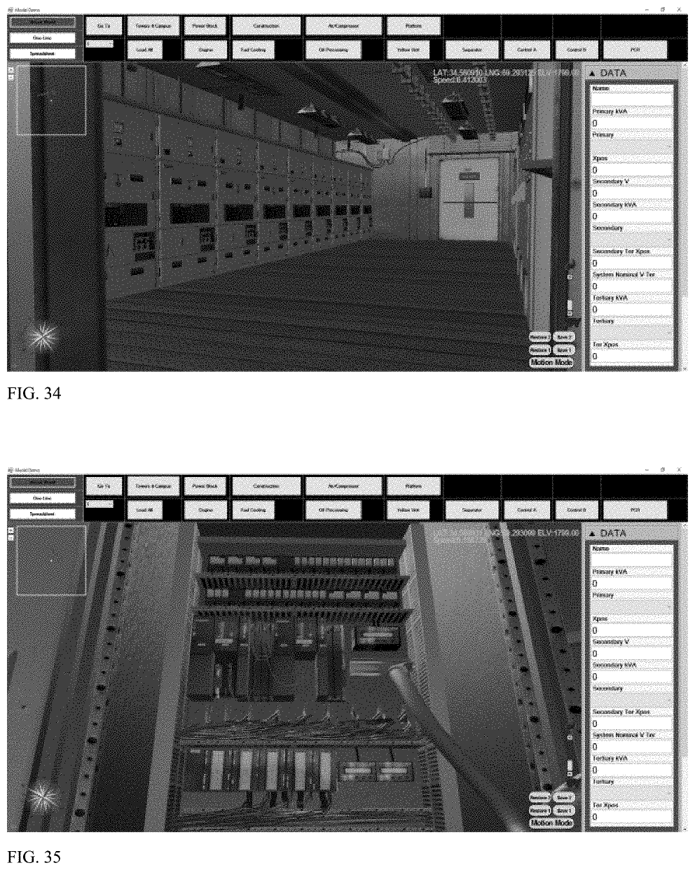

FIG. 2 is a simplified block diagram illustrating a computer-implemented system 500 may include an electric utility power transmission and distribution grid 510 (“grid”), in an exemplary embodiment. The grid 510 may include infrastructure including a plurality of utility assets 512 distributed on a utility power line route 514 in a geographic area 516. The grid 510 may be identical to the grid shown in FIG. 34 which includes an exemplary utility power line route in a geographic area.

Referring to FIG. 2, computer-implemented system 500 may include a virtual world platform 520. Commercially available products which may embody a suitable virtual world platform 520 may include OpenSimulator (opensimulator.org) and Unreal Engine (Epic Games, Cary, N.C.). Virtual world platform 520 when executed may be capable of providing a navigable simulation of a three-dimensional virtual environment. Virtual world platform 520 may be embodied in an application or codebase of computer-executable instructions executed by a processor 530 configured to execute computer-executable instructions. In an embodiment, processor 530 may be a scalable processor resource of a cloud server 540 accessible in a network cloud via a data communications network 550 such as the Internet. Processor 530 of cloud server 540 may access scalable cloud storage 560 via the network 550. Virtual world platform 520 executed by processor 530 may generate an integrated model 600 including an integrated visualization 620 of a plurality of models, as explained in further detail.

Referring to FIG. 2, computer-implemented system 500 may include a geospatial topological model 700. Geospatial topological model 700 may include geospatial information and terrain information, including elevation information, for the utility power line route in the geographic area.

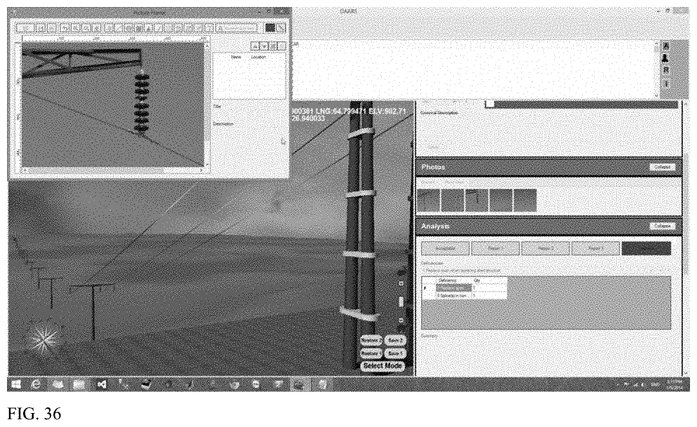

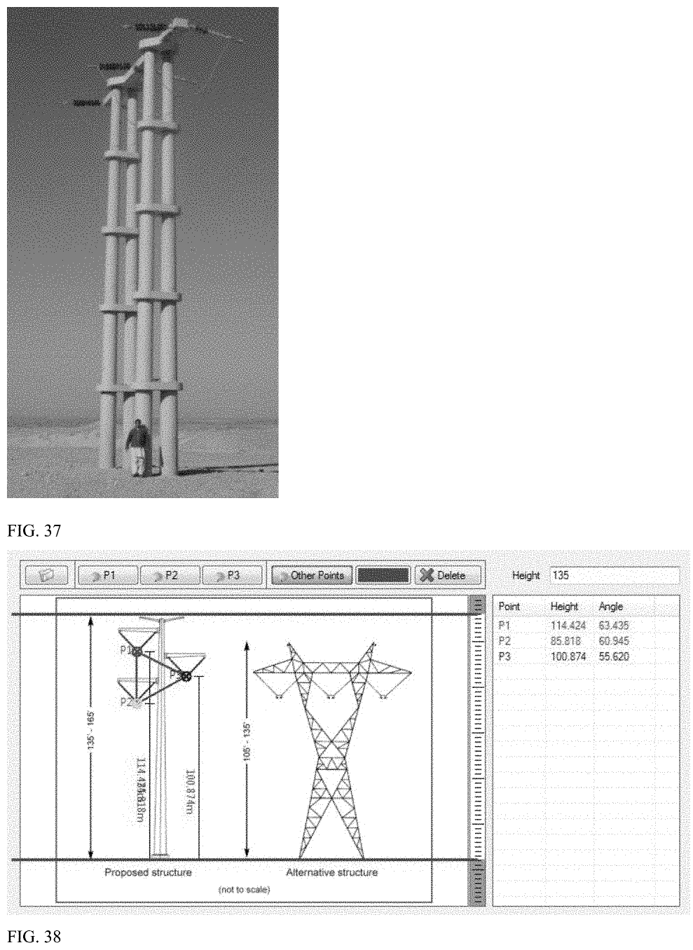

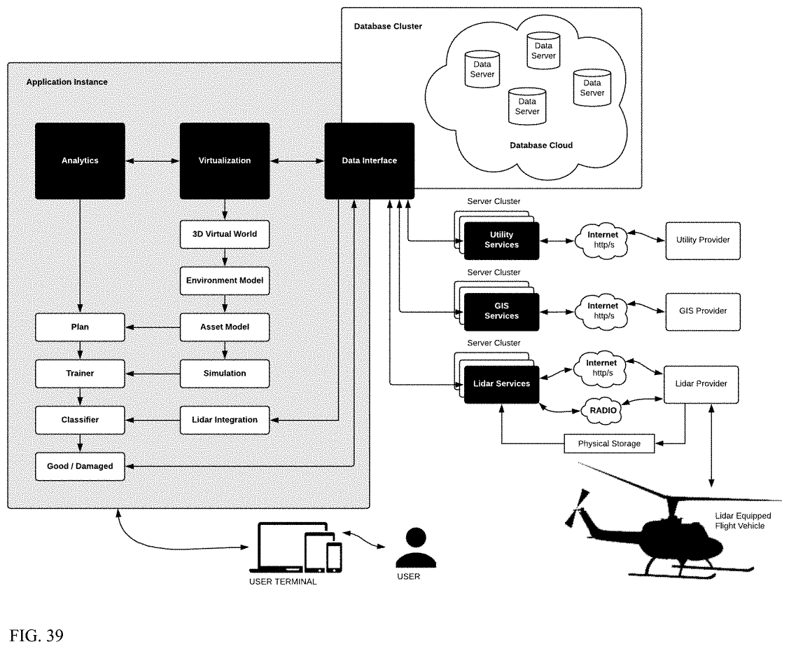

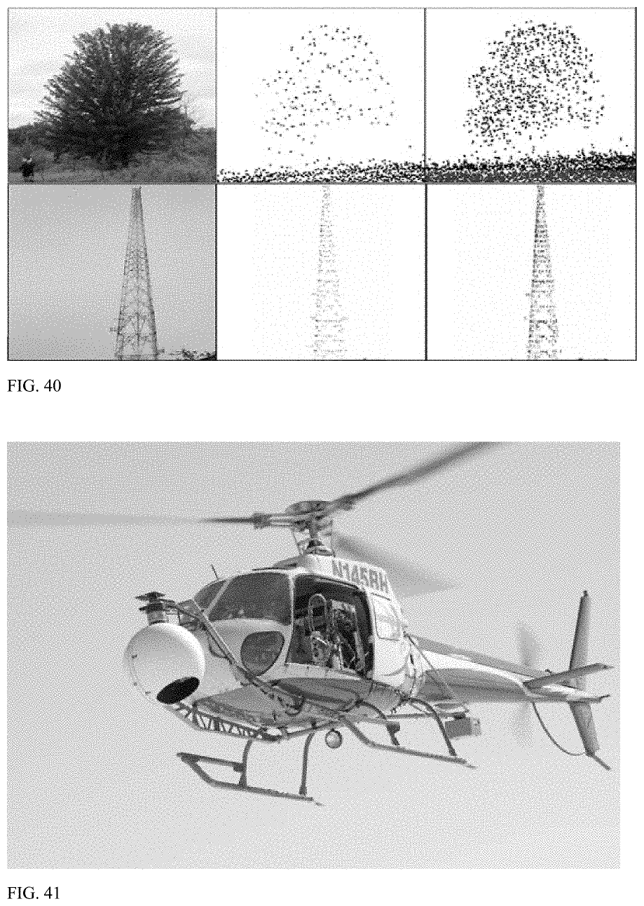

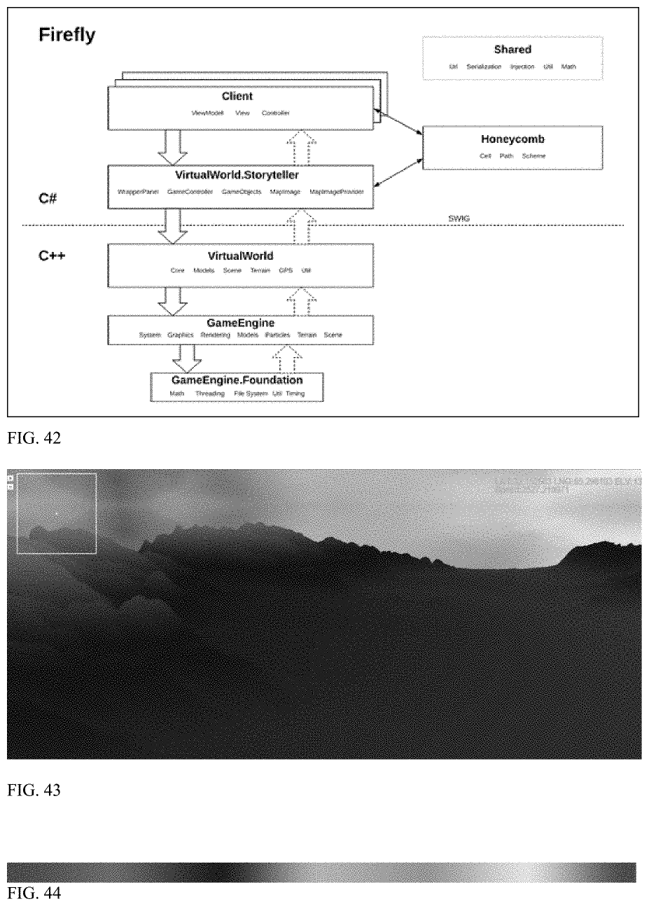

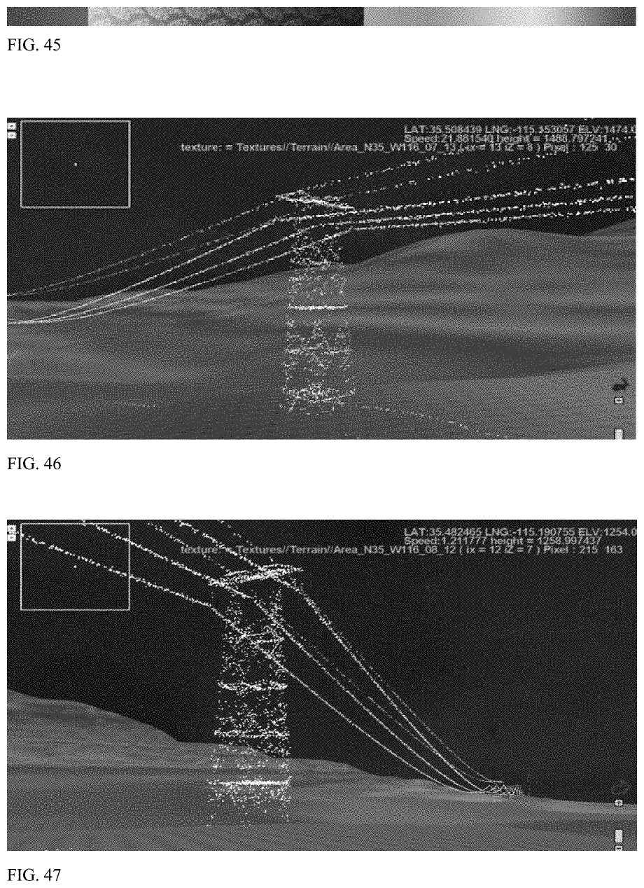

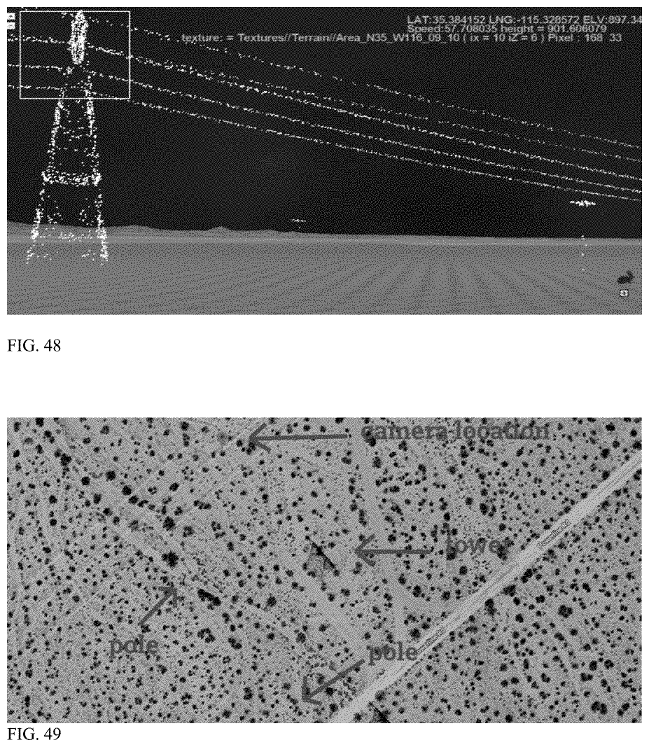

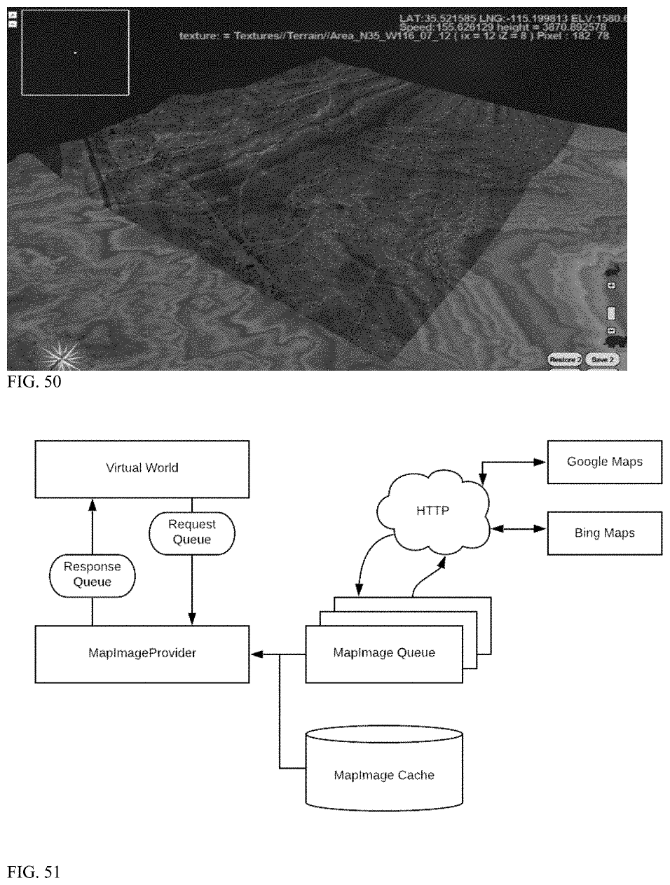

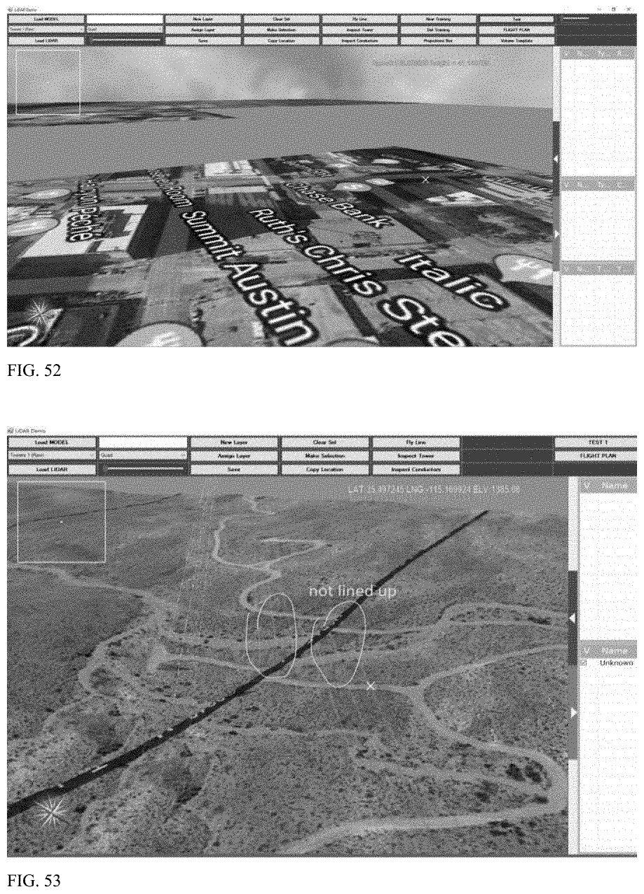

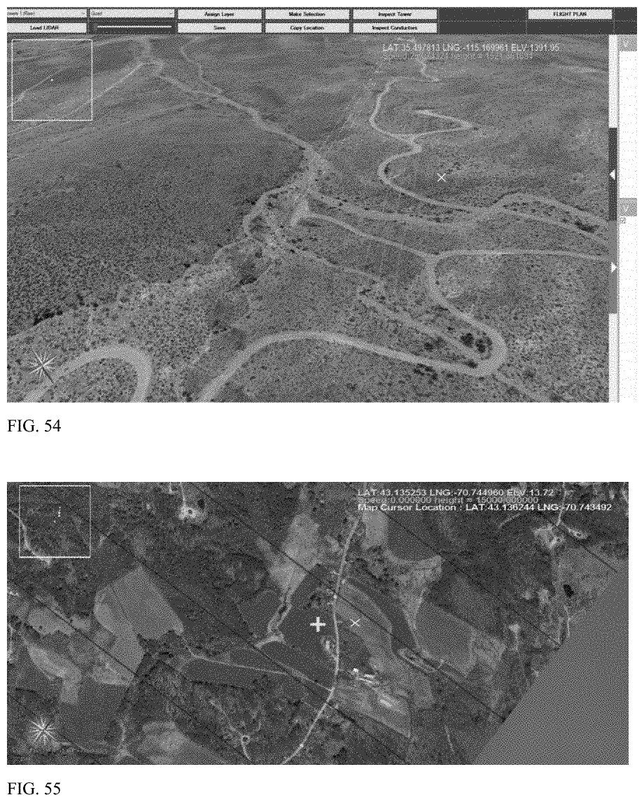

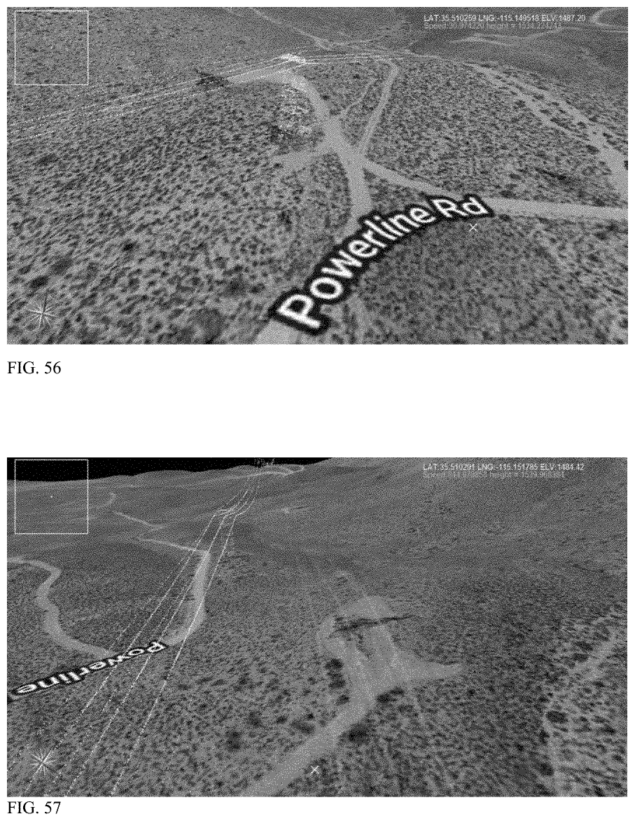

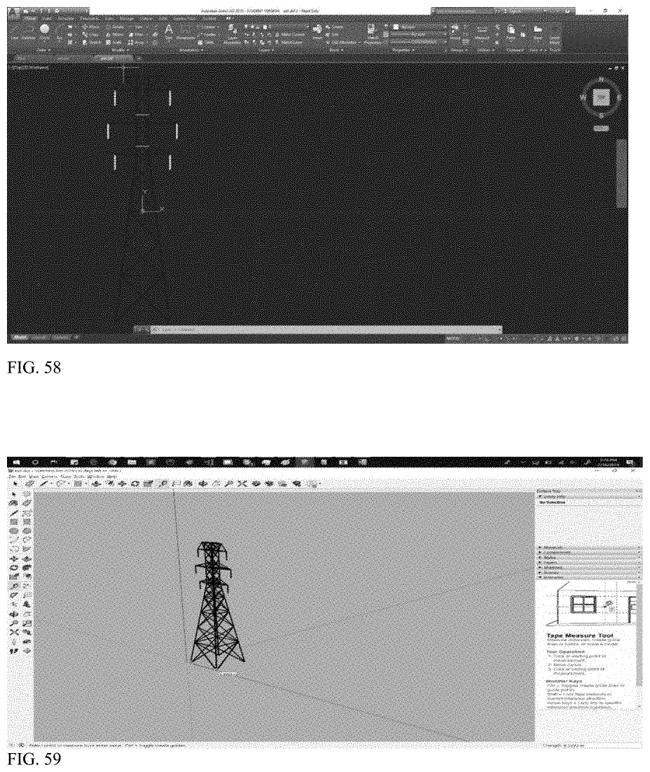

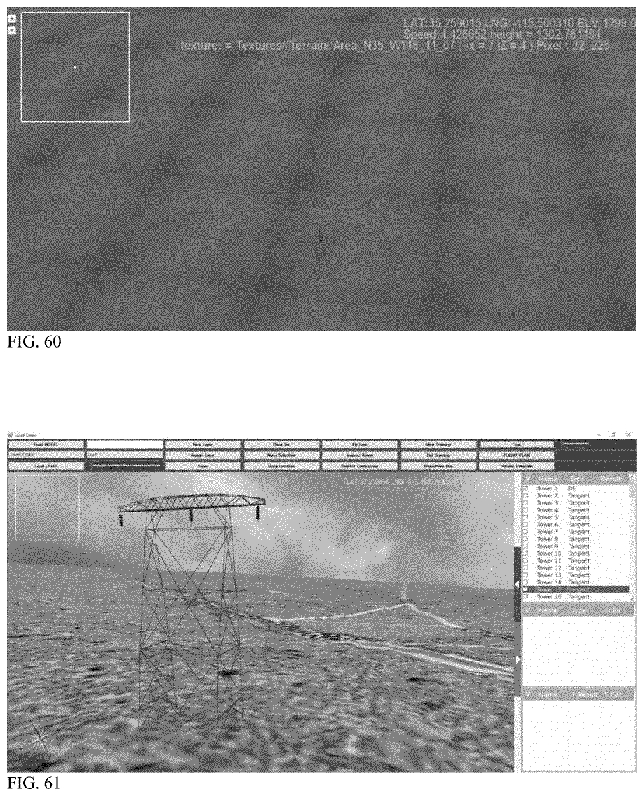

Referring to FIG. 2, computer-implemented system 500 may include infrastructure model 800. Infrastructure model 800 may include a plurality of utility asset model entities 820 for the plurality of utility assets 512 on utility power line route 514. The infrastructure model 800 may include three-dimensional asset geometry information (shown generally in FIG. 36) for each of the plurality of utility assets 512.

As shown in FIG. 2, computer-implemented system 500 may include power line imaging data 900 collected by imaging or scanning, in the real world, physical infrastructure consisting of the plurality of utility assets 512 on utility power line route 514 in the geographic area 516. Collection of power line imaging data 900 may be performed, for example, by a Lidar imaging system carried on a flight platform such as a helicopter, plane, or unmanned aerial vehicle (UAV) flown along the power line route. The collected power line imaging data 900 may include utility asset imaging data 920 in relation to the plurality of utility assets 512. The power line imaging data 900 may include geospatial location information, which may be geographic positioning system (GPS) coordinates, for the collection locations of the power line imaging data 900. The collected power line imaging data 900 may be stored in a horizontally scalable database, which may be embodied, for example, in cloud storage 560. In an embodiment, the power line imaging data 900 may include lidar data 930. The power line imaging data 900 may include telemetry data. The power line imaging data 900 in an embodiment may include lidar data and telemetry data. In an embodiment, the power line imaging data 900 may be selected from: lidar data 930, telemetry data, photography data, and photogrammetry data.

As shown in FIG. 2, computer-implemented system 500 may include a navigable virtual environment 610 rendered by a processor 530. The navigable virtual environment 610 may include an integrated model 620 including integrated visualization 620 of the geospatial topological model 700, infrastructure model 800, and power line imaging data 900.

Referring to FIG. 2, computer-implemented system 500 may include a virtual viewer 640 (“viewer”) of the navigable virtual environment 610. Viewer 640 may be provided by a processor 530 in relation to the navigable virtual environment 610. Viewer 640 may include a point of view 650. For each point of view 650, viewer 640 may have a viewer orientation or attitude 655 relative to x,y,z axes. For any point of view 650 and viewer attitude 655, viewer 640 includes a virtual view 660 on the modeled utility power line route 514 depicted in the navigable virtual environment 610. Each virtual view 660 from a point of view 650 and attitude 655 may include the integrated visualization 630 of the integrated model 620. The integrated visualization 630 may include infrastructure model image information, including utility asset image information in corresponding utility asset model entities 820 for corresponding of the plurality of utility assets 512. System 500 may output the virtual view 660 to a display 980. System 500 may include the viewer 640 being navigable by execution of a processor 530 to navigate between static positions in relation to the rendered navigable virtual environment 610 to provide a plurality of virtual views 660 on the modeled utility power line route 514 depicted in the navigable virtual environment 610. The plurality of virtual views 660 may include the integrated visualization 630, which may include infrastructure model image information 830, including utility asset image information 840, for the plurality of utility assets 512.

Referring to FIG. 2, computer-implemented system 500 may include a simulation engine 860 executable in relation to the navigable virtual environment 610. Simulation engine 860 may be capable of automating navigation of viewer 640 in relation to the navigable virtual environment 610 to provide a simulated time series of virtual views 660 and simulated movement of the viewer 640 along the modeled power line route 514 depicted in the navigable virtual environment 610. In an embodiment, for example, the simulation engine 860 may automate motion and navigation of the viewer 640 along the simulated flight path of a virtual aircraft inspecting the infrastructure model along the power line route 514 depicted in the navigable virtual environment 610. In an embodiment, for example, the simulation engine 860 may automate motion and navigation of the viewer 640 along the simulated flight path of the aerial platform that carried the imaging system to collect power line imaging data 900 along the power line route 514.

System 500 including simulation engine 860 thus may provide a plurality of virtual views to a processor 530 to identify damage visible in the integrated visualization 630, which may include the infrastructure model image information 830 and utility asset image information 840 for the plurality of utility assets 512 on the power line route 514 depicted in the navigable virtual environment 610.

Referring to FIG. 2, computer-implemented system 500 may include analytics, including a classifier 950. Classifier 950 may operate to classify modeled utility assets 512 depicted in a virtual view 660, or plurality of same, as being in normal condition or damaged condition based on visual information. Classifier 950 may include a trained classification algorithm 960 executed by a processor 530, in run-time mode, to compare the collected power line imaging data 900 to reference classification information. The trained classification algorithm, operated in training mode during a training period, may develop the reference classification information in relation to receiving reference power line imaging data 900 for a plurality of utility assets 512 classified in known normal condition or damaged condition. It will be understood that the classification of normal condition or damaged condition, during the training period, is known and the known condition may be provided to the trained classification algorithm for developing contours of normal condition, damaged condition, or both. It will be understood that the trained classification algorithm may be a suitable machine learning algorithm or artificial intelligence algorithm. In an embodiment, the trained classification algorithm, executing the training mode during the training period, may develop the reference classification information in relation to receiving reference power line imaging data 900 in a reference view of infrastructure including a utility asset, where the reference view may be a virtual view, a real-world image, or both.

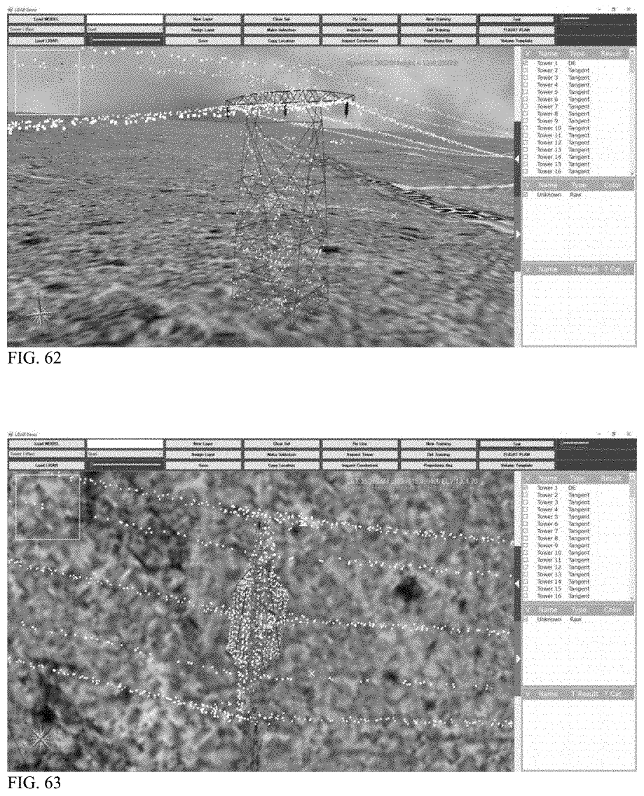

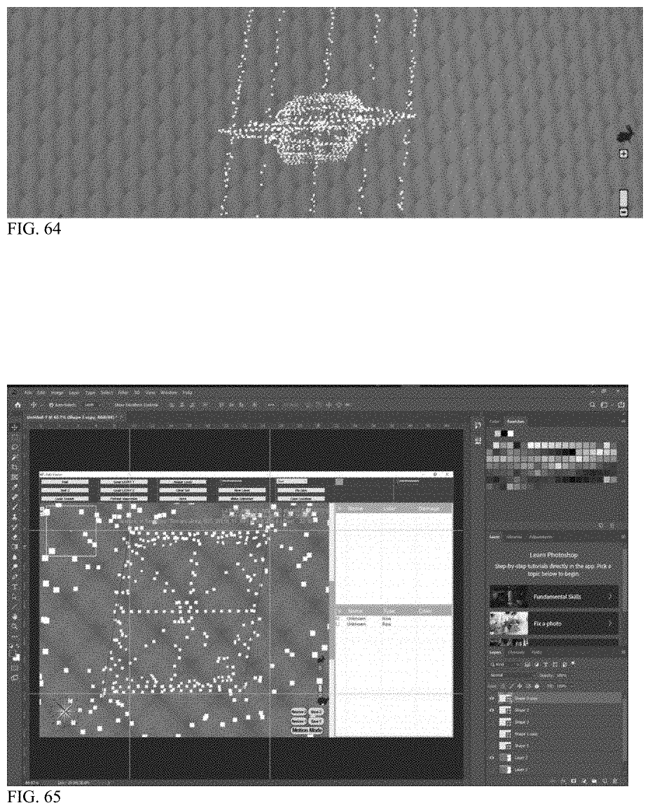

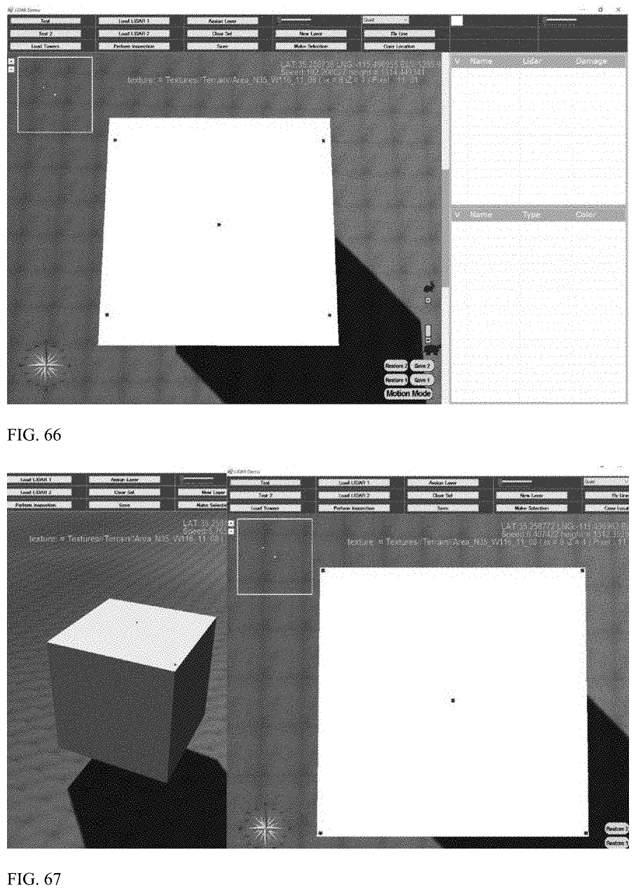

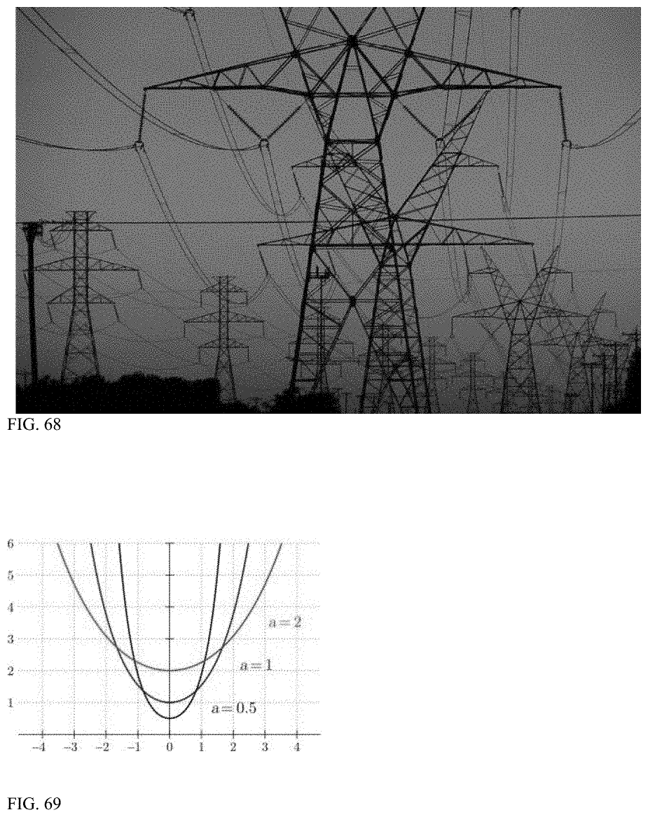

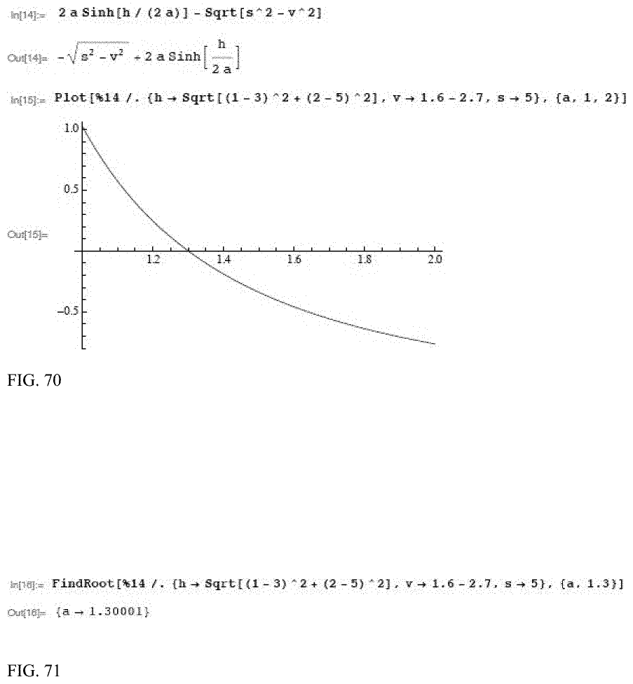

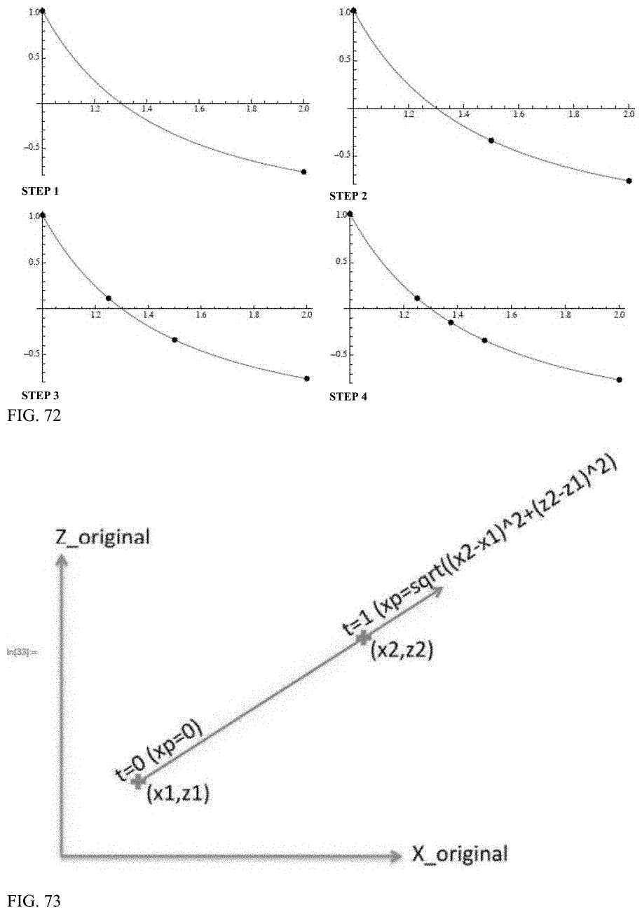

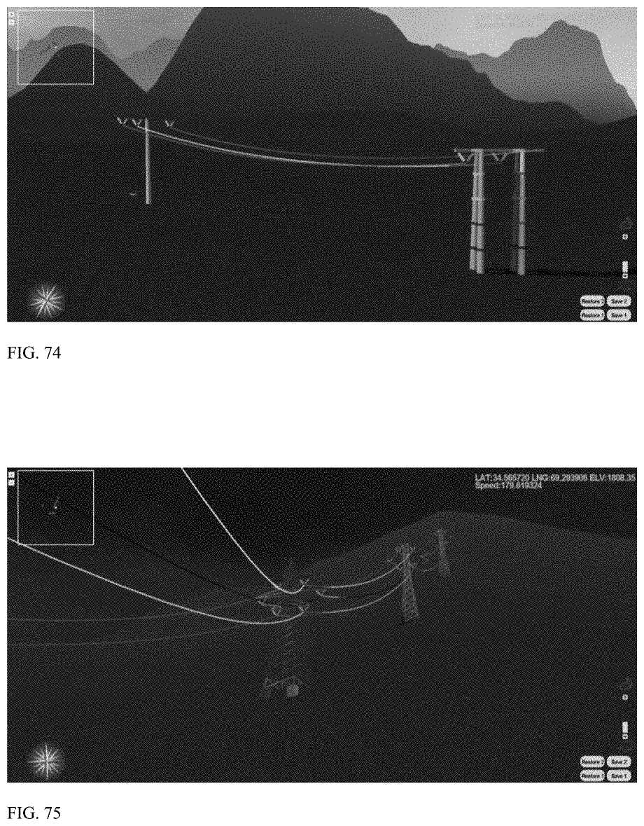

As shown in FIGS. 61-139, power line imaging data for all utility assets, such as transmission towers, on the power line route may be collected and compared to known geometry of the utility assets. The trained classification algorithm 960 may compare the collected power line imaging data to correlations between power line imaging data for utility assets in normal condition and power line imaging data for utility assets in damaged condition, and thus classify the condition of each utility asset.

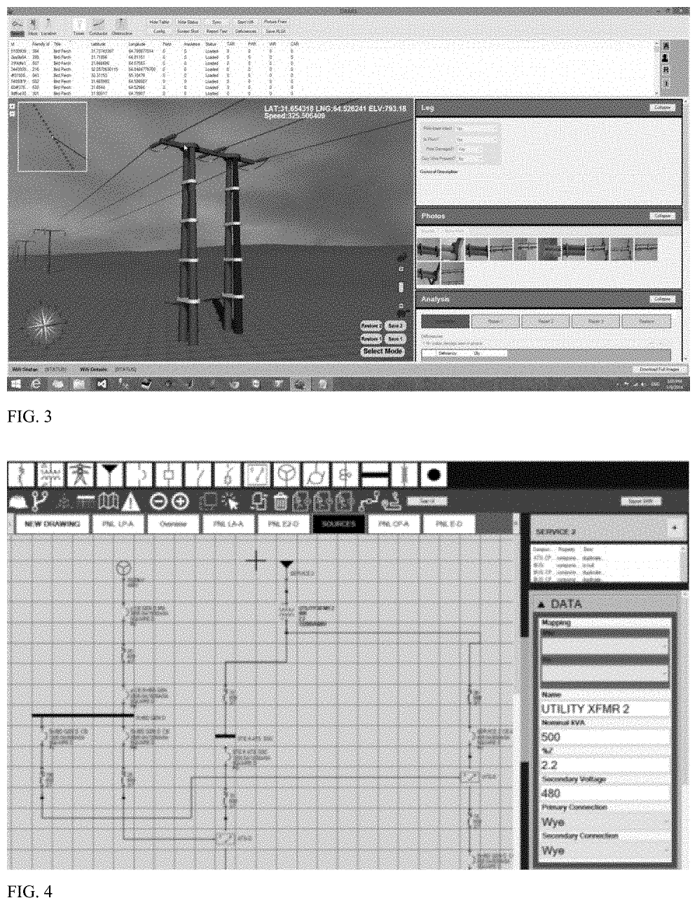

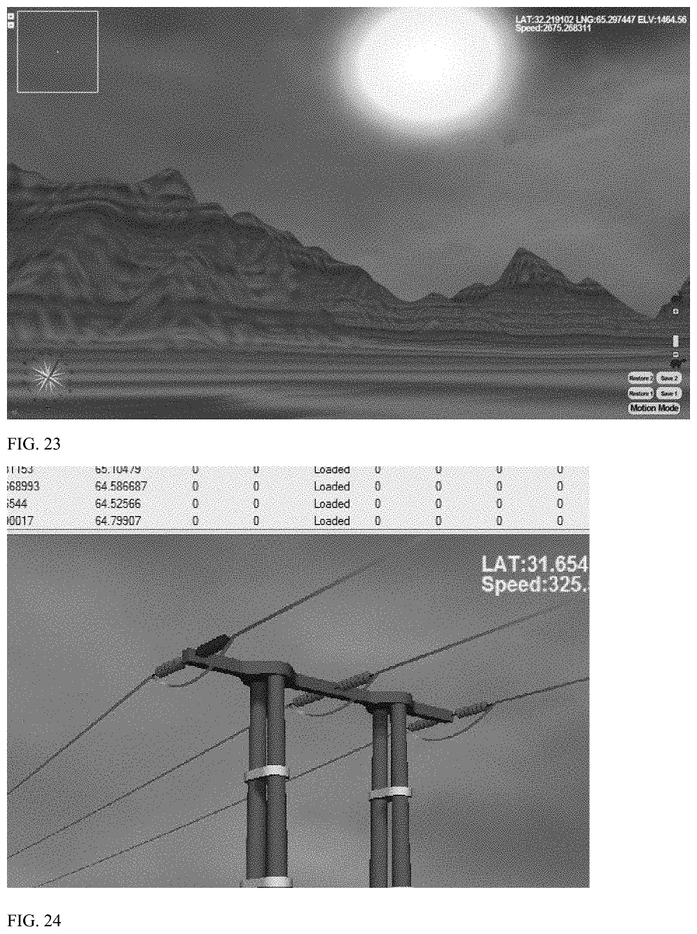

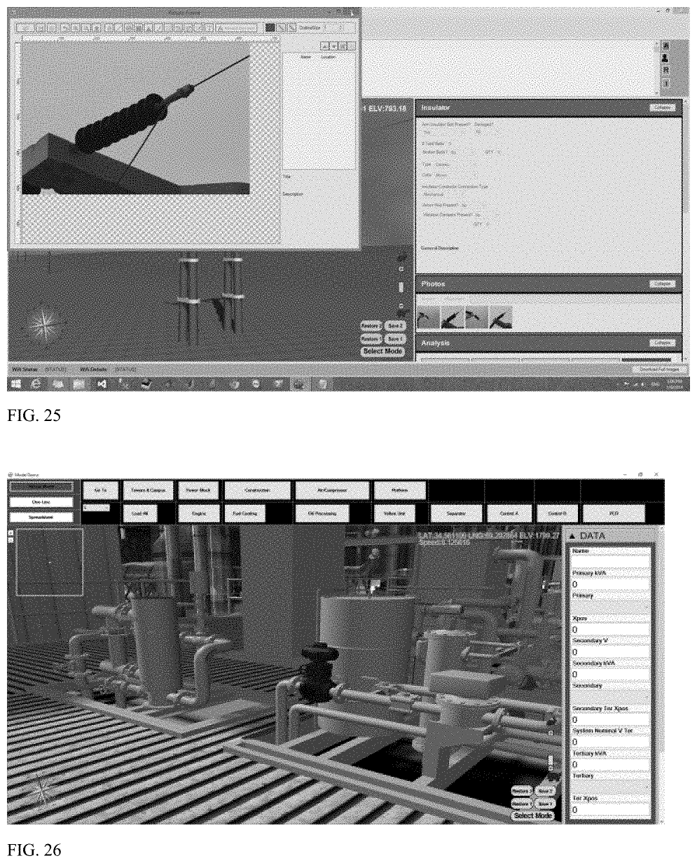

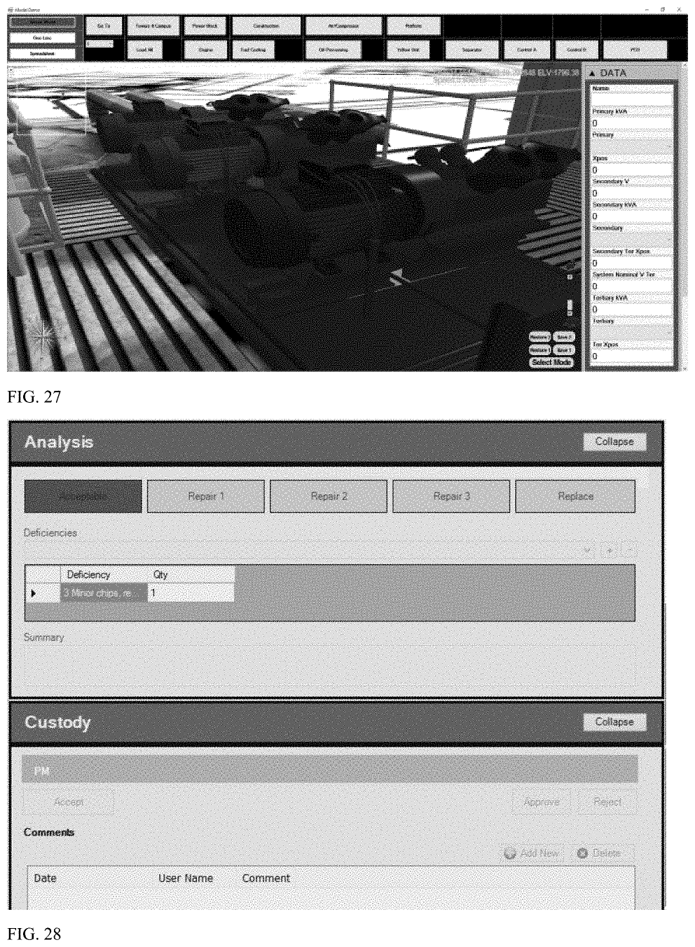

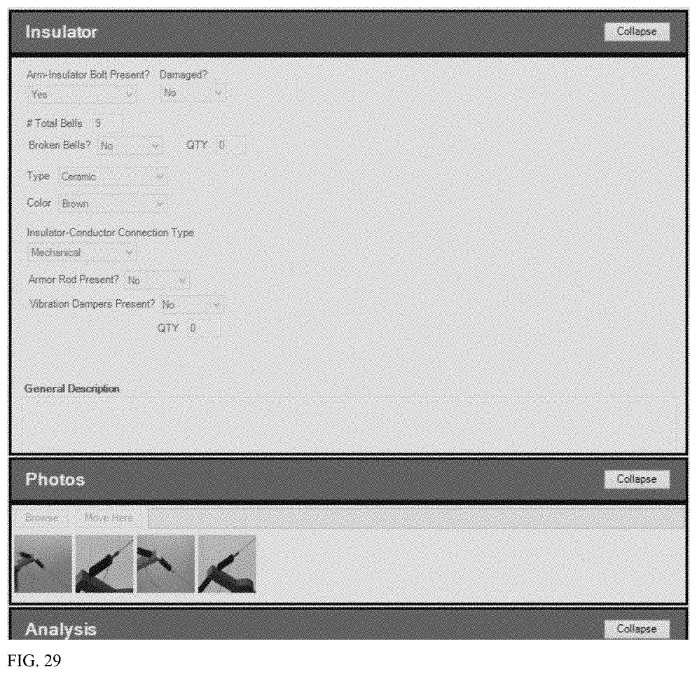

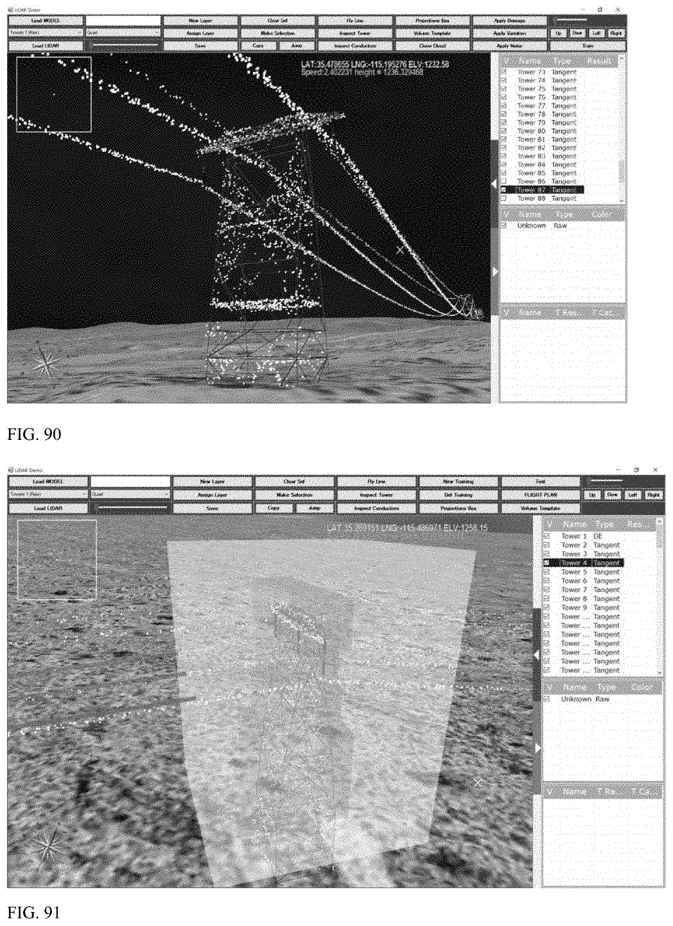

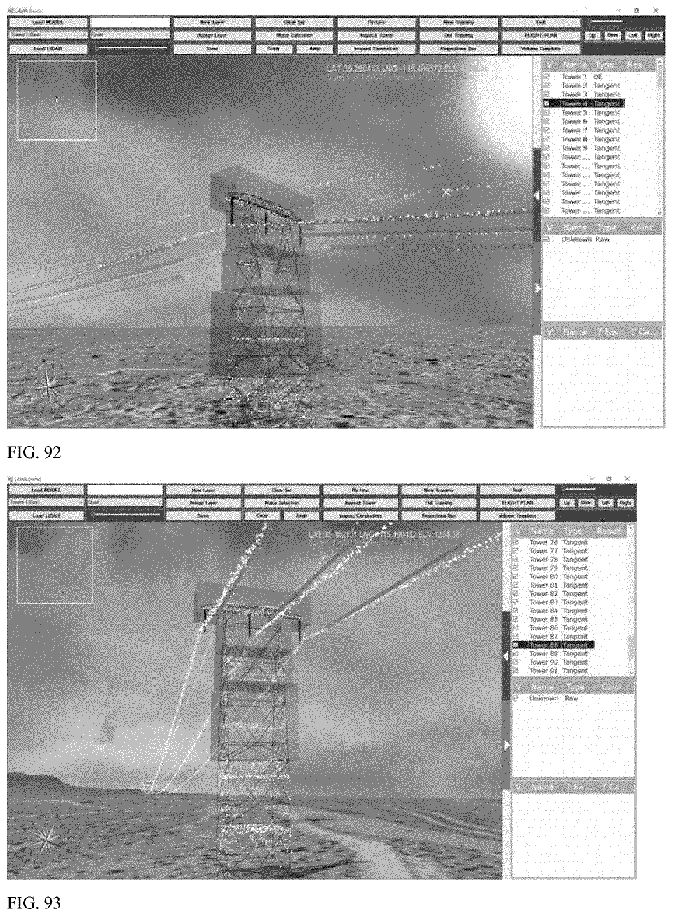

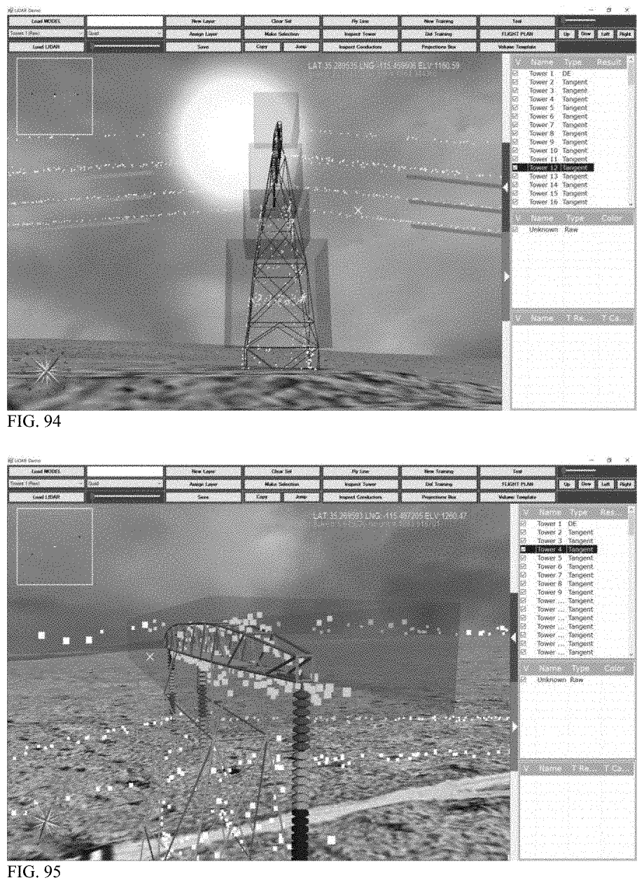

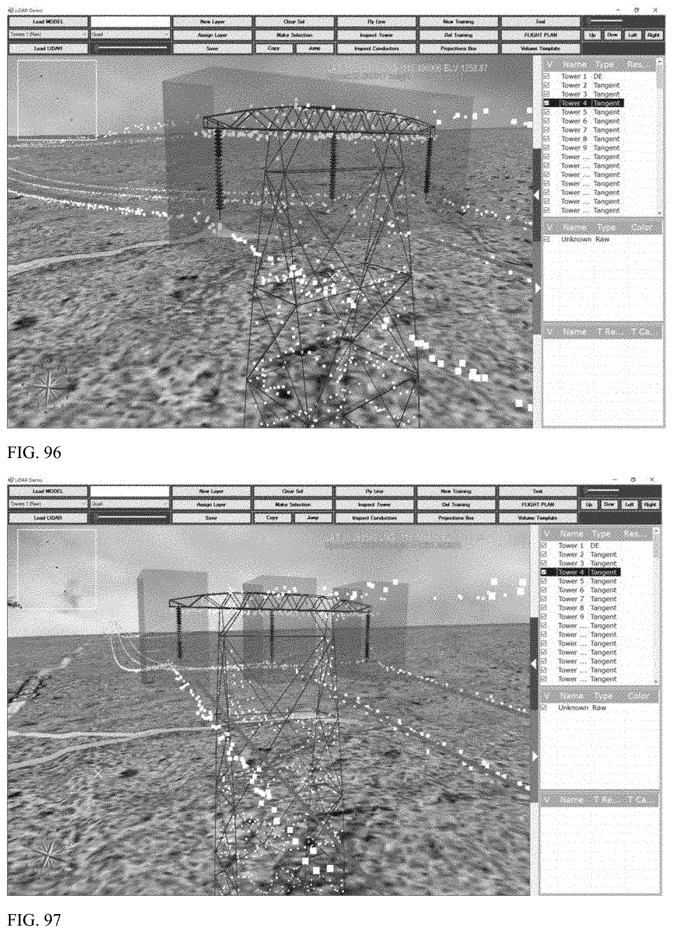

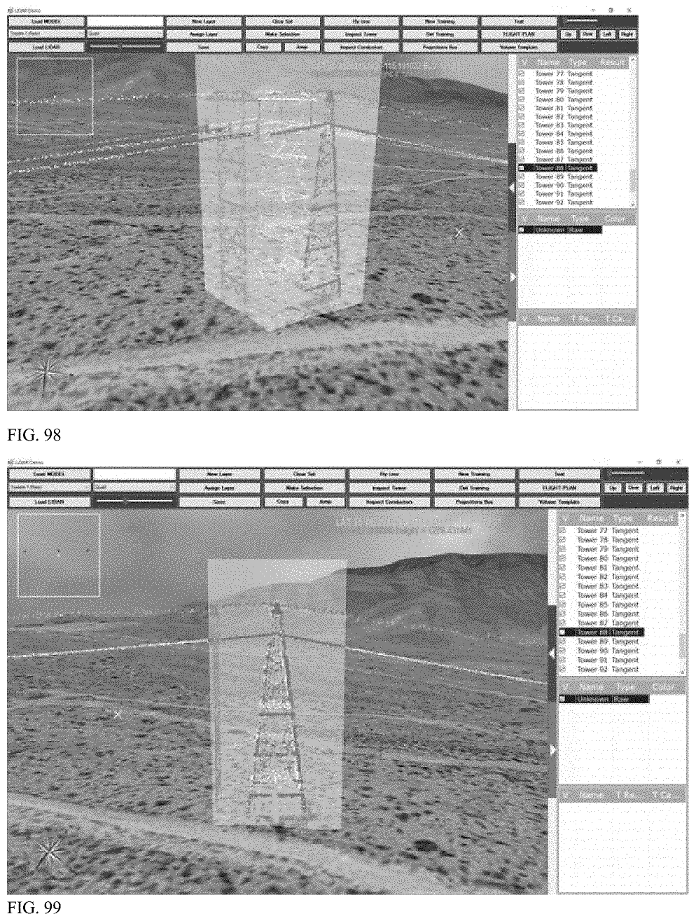

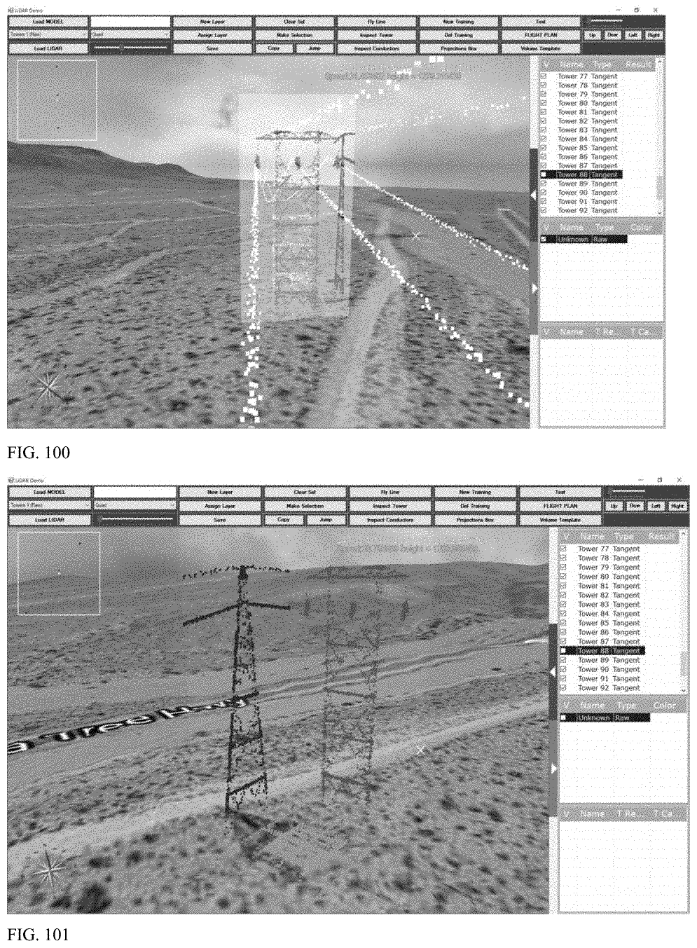

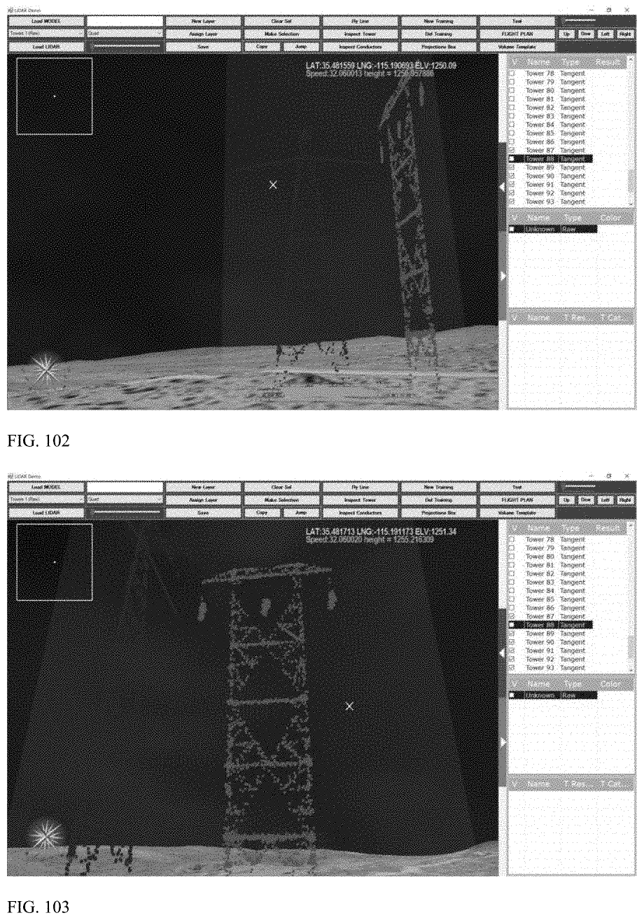

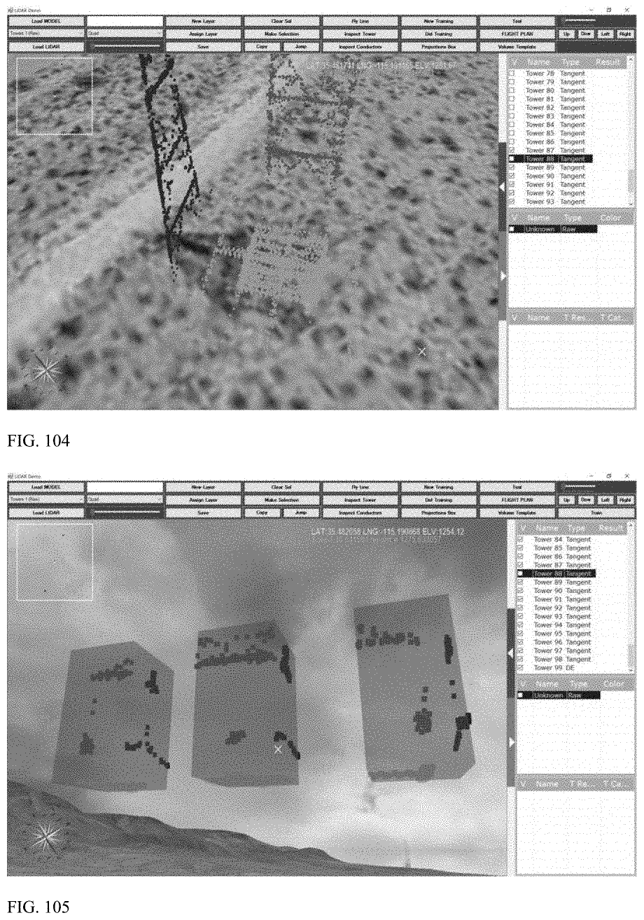

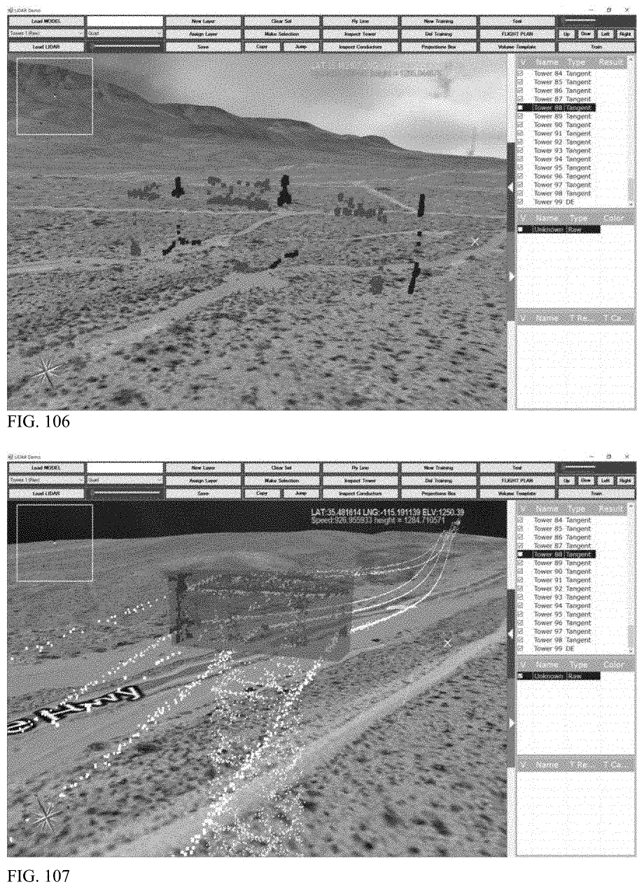

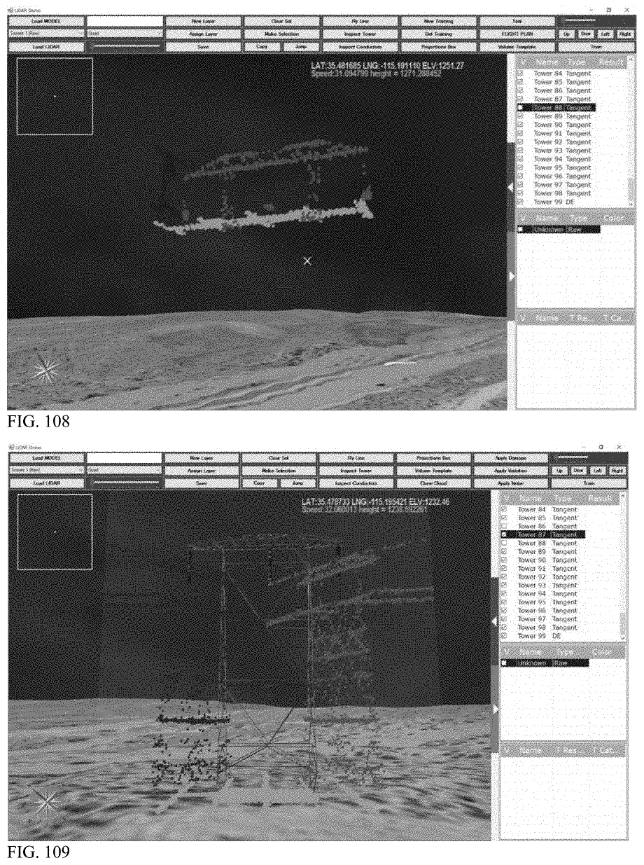

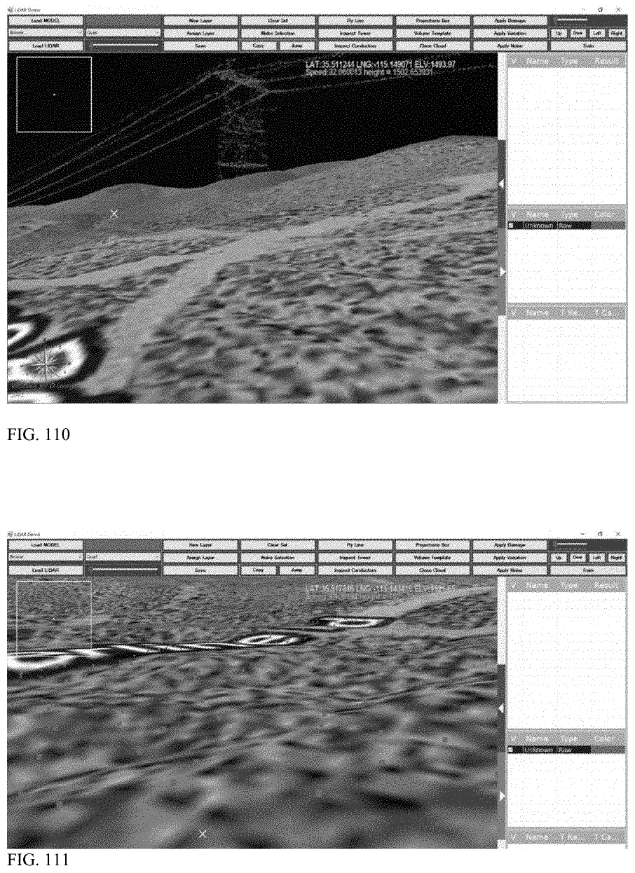

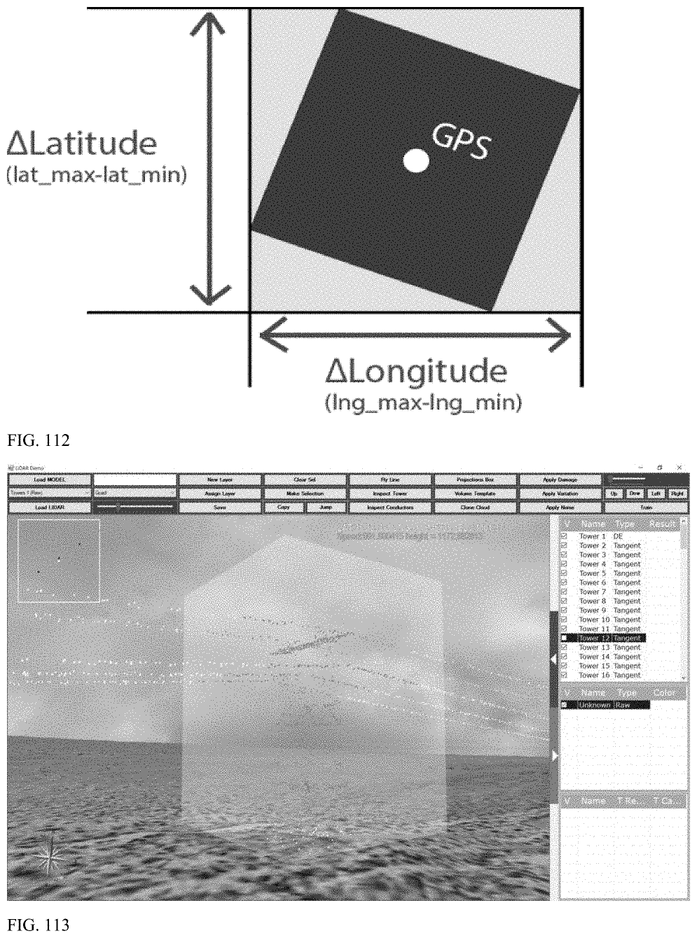

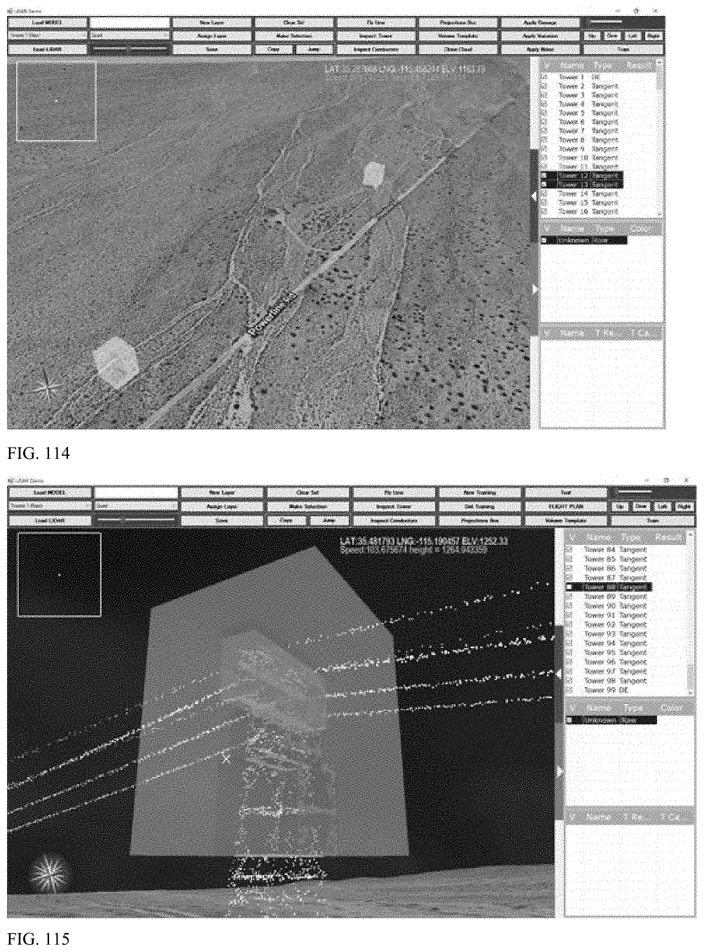

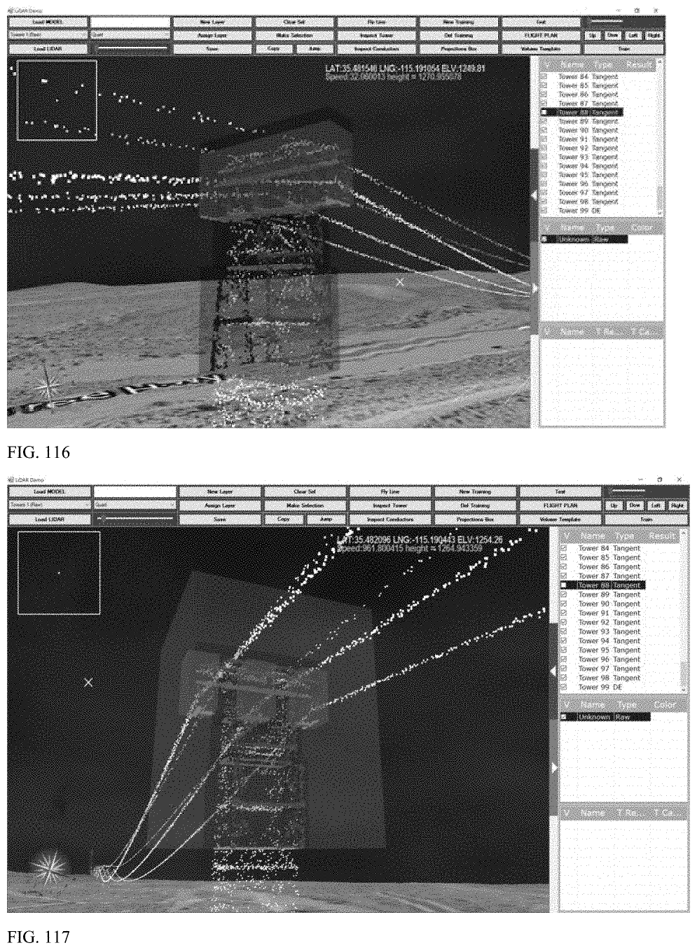

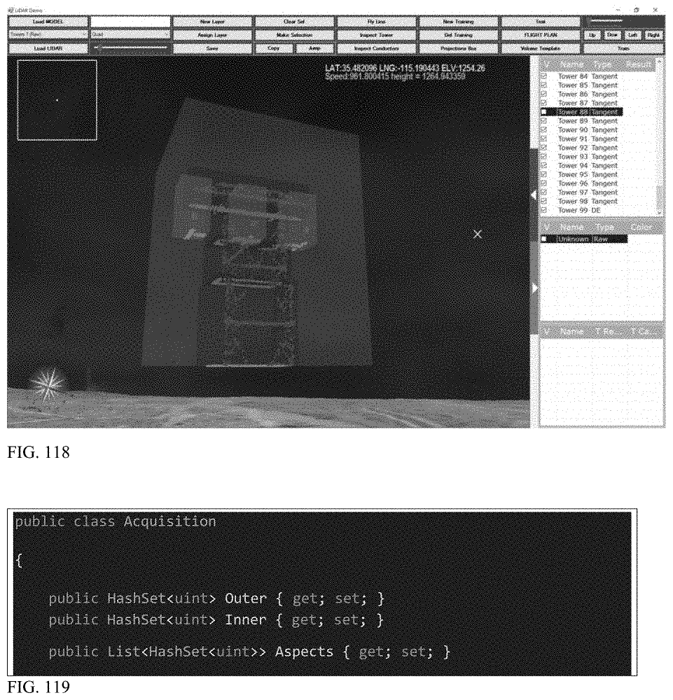

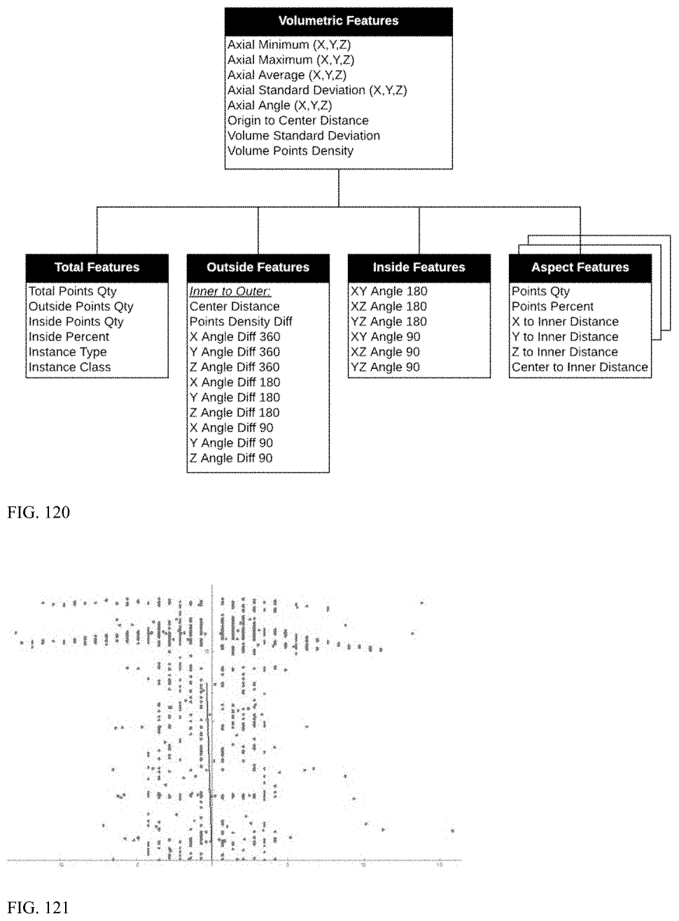

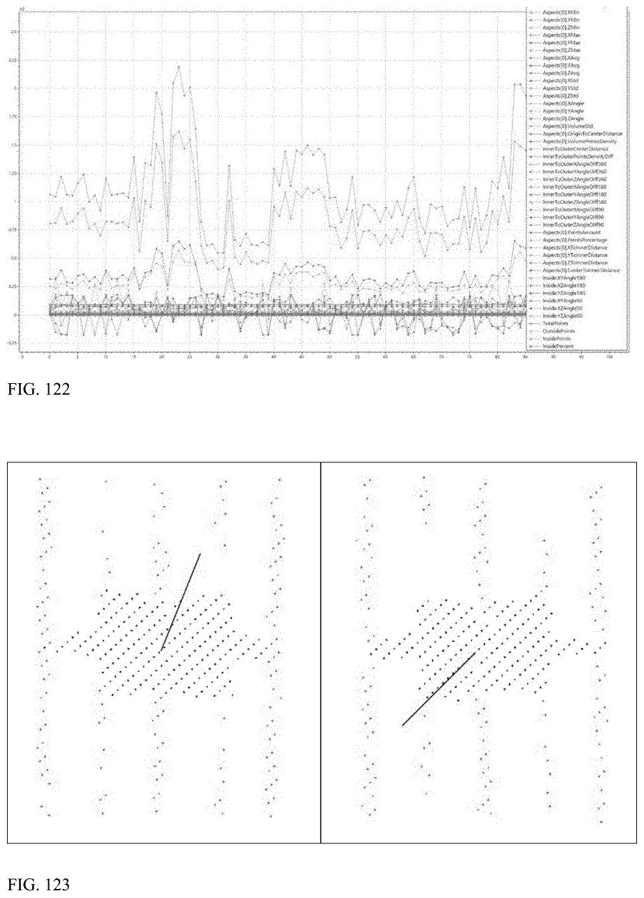

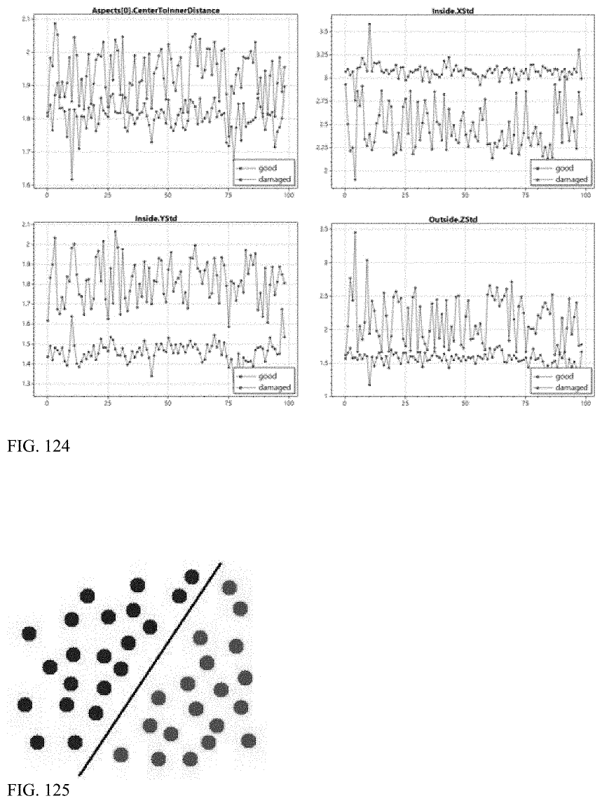

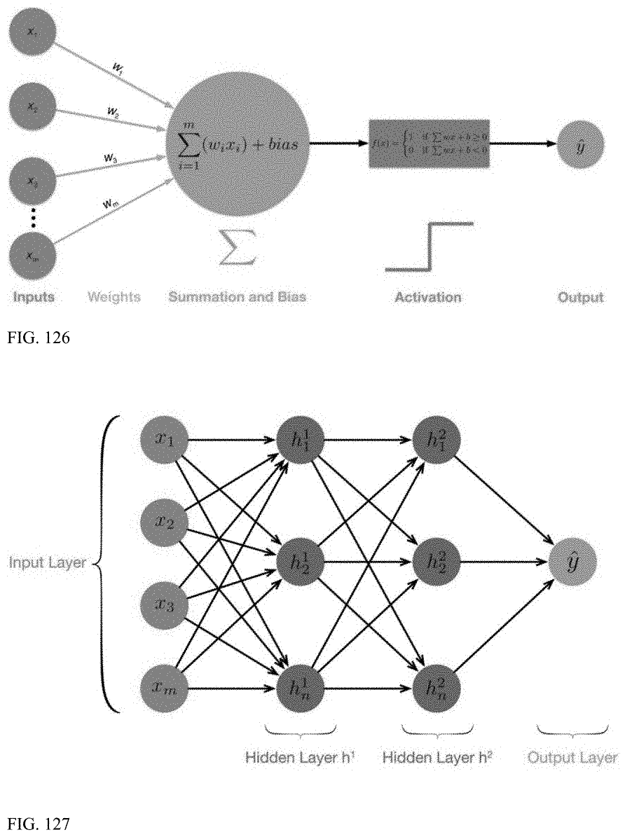

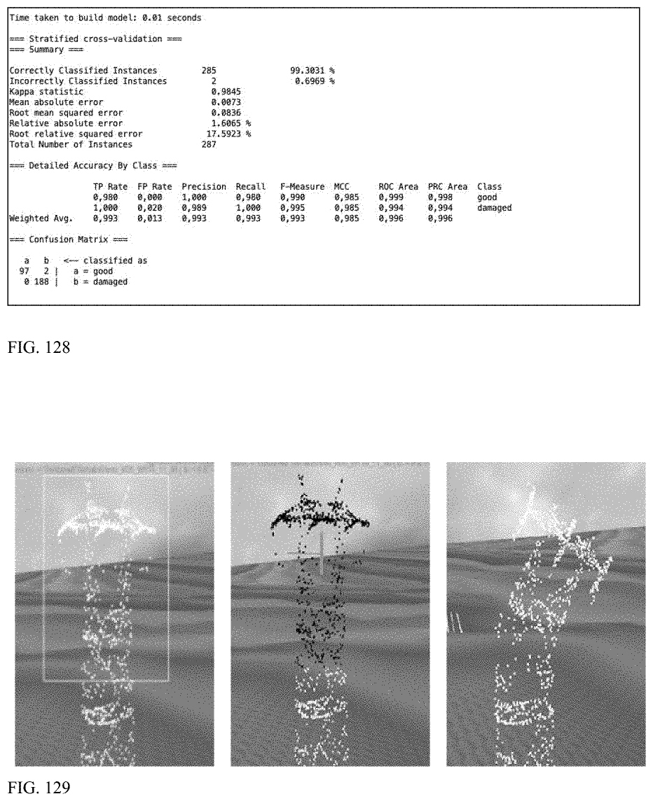

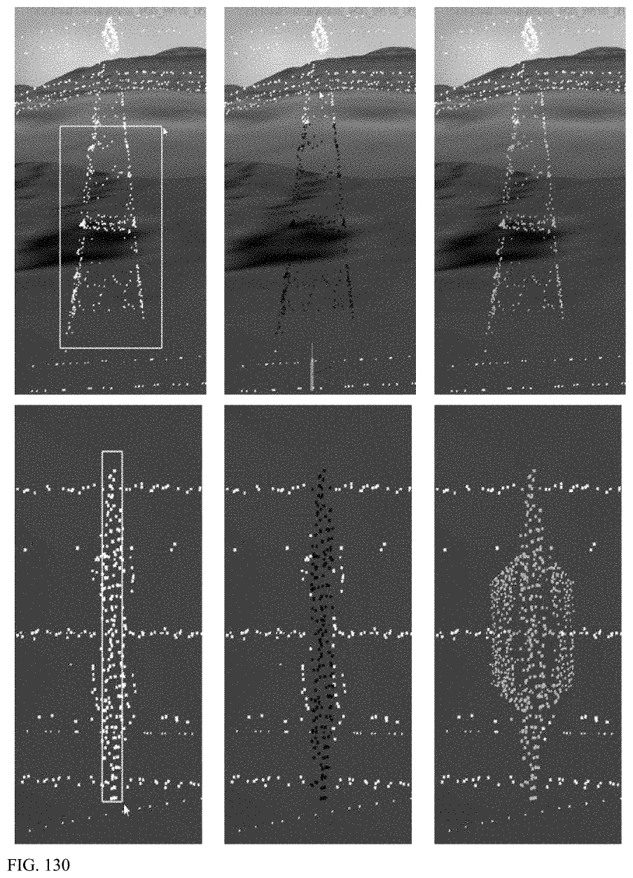

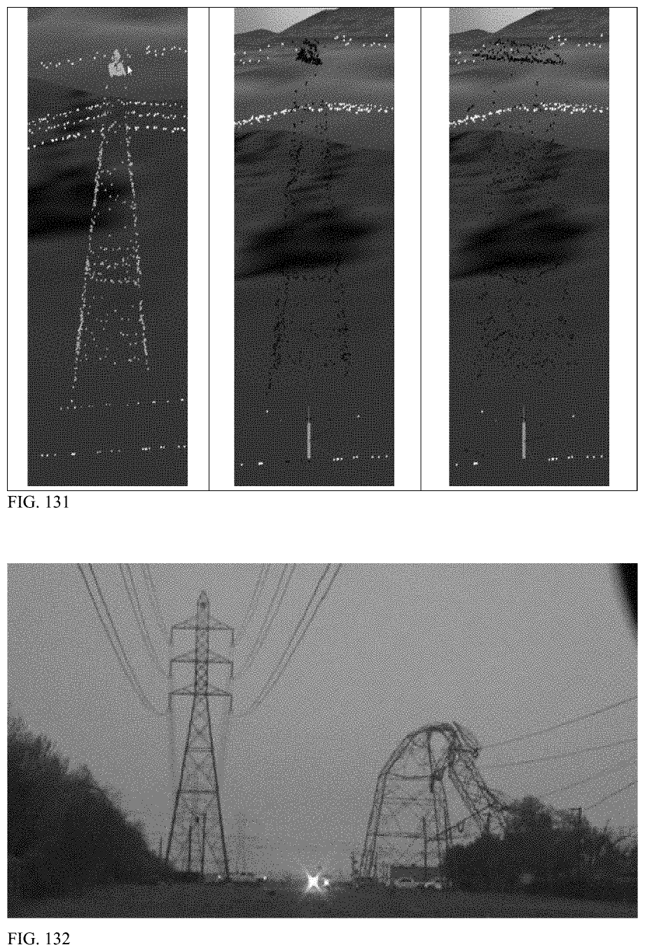

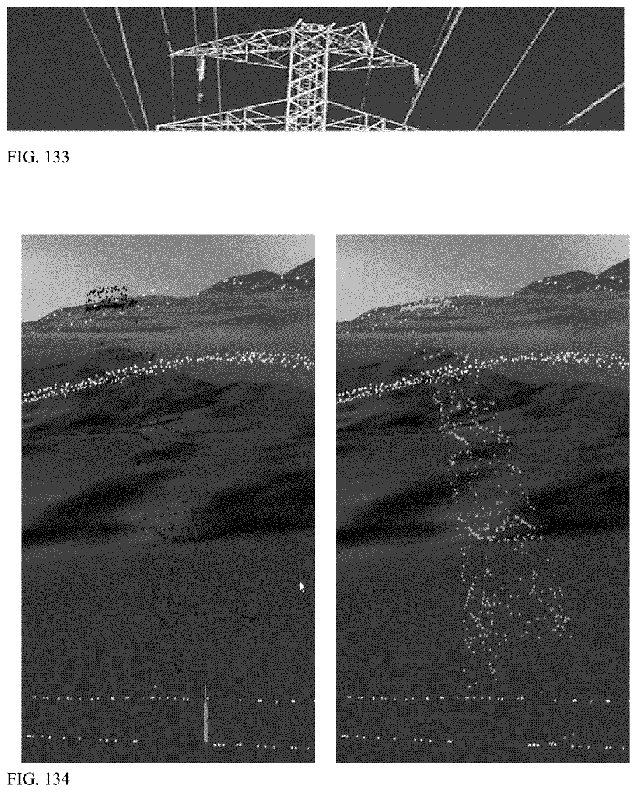

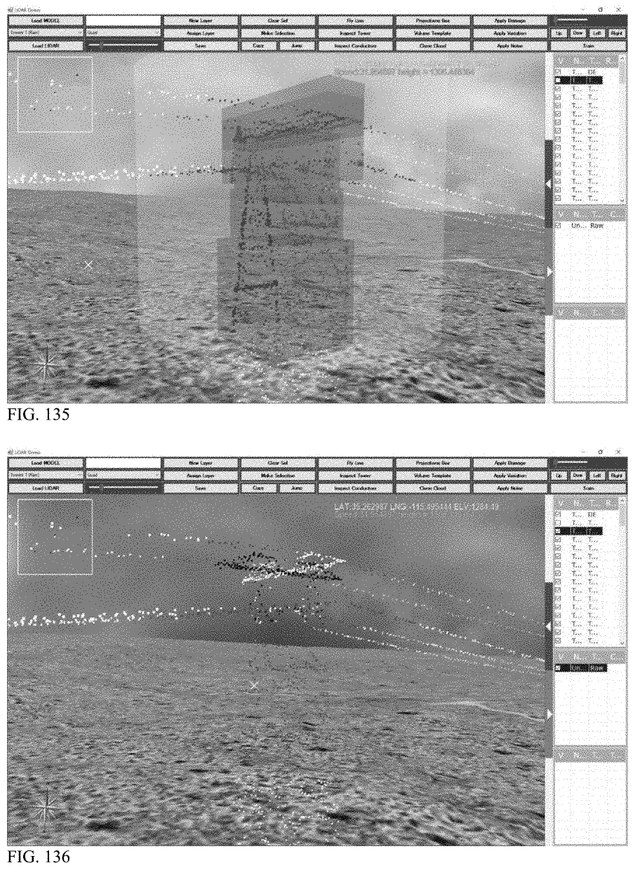

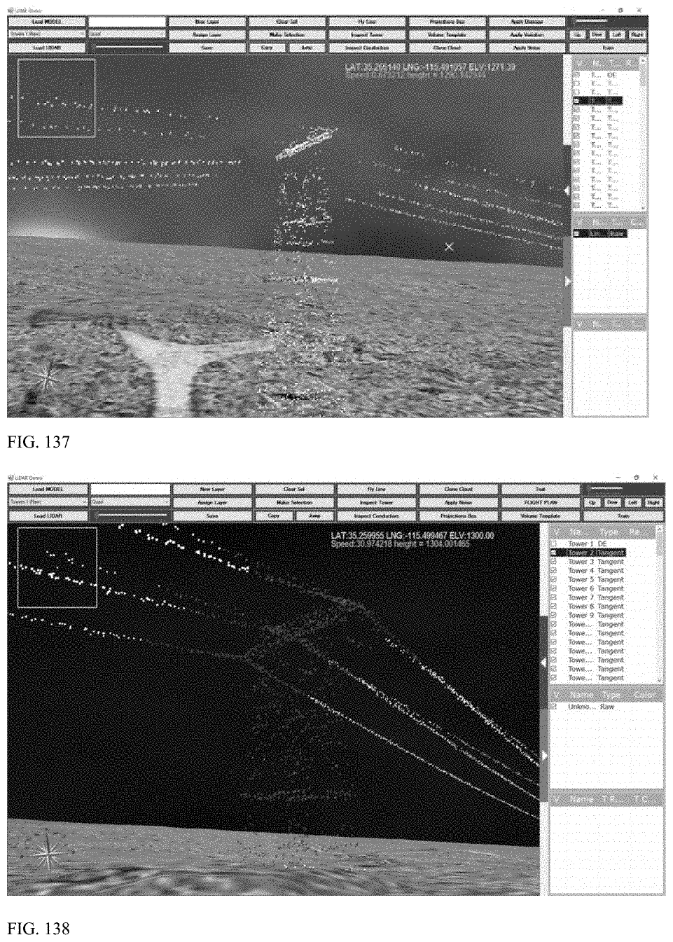

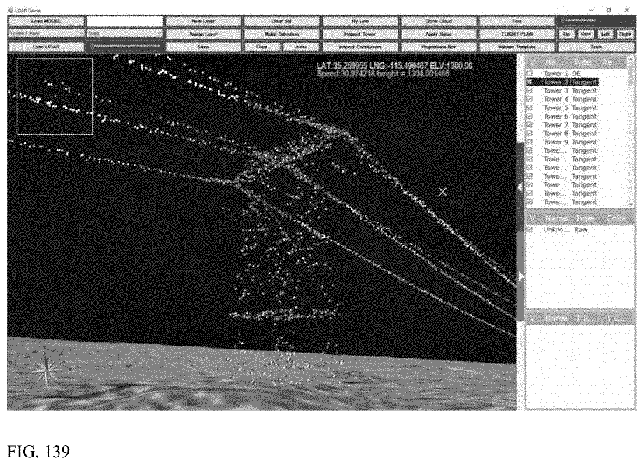

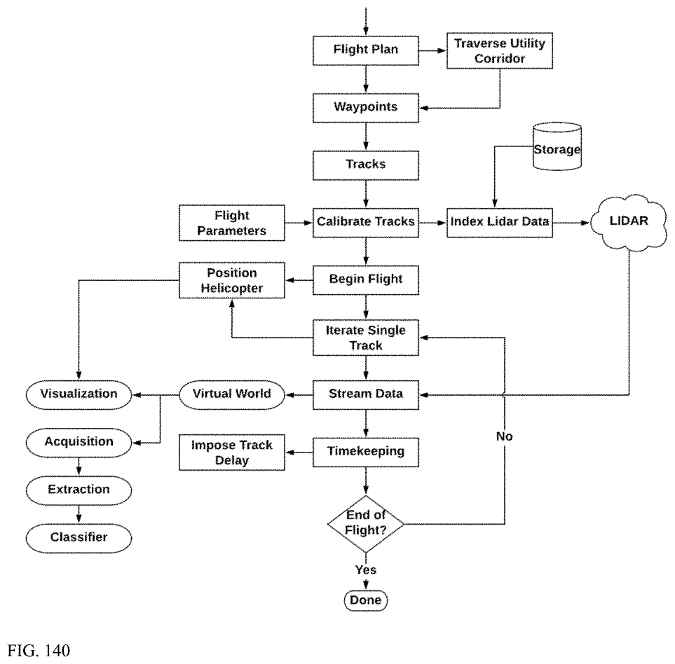

As shown in FIGS. 91-108, in an embodiment analysis and classification may be performed for power line imaging data, such as lidar data, in relation to a volume of interest. In an embodiment, hierarchies of volume of interest may be implement for such analysis. In an embodiment, for example, volume of interest may be defined as outer box, inner box, and aspects. An outer box and multiple inner boxes are shown placed around a tower in FIG. 91. With the opacity of the outer box reduced, the inner boxes may be visible, as shown in FIG. 90. Multiple boxes of different dimensions may be defined which combined together form an inner volume. They may be designed to be centered at a GPS location and then extend out from that point in all directions, having the effect of wrapping around a point cloud representing a utility asset such as a transmission tower. Correlations between geometry of each utility asset may be determined in comparison to power line imaging data, such as lidar data. An integrated model including an infrastructure model may include models of a variety of utility assets, including power generation, transmission, and distribution. As shown in FIG. 3 and FIGS. 24-30, each of the utility assets may be modeled in a respective utility asset data entity which may be virtualized in the virtual world platform. Where a utility asset is selected, data records of the utility asset data entity are accessed.

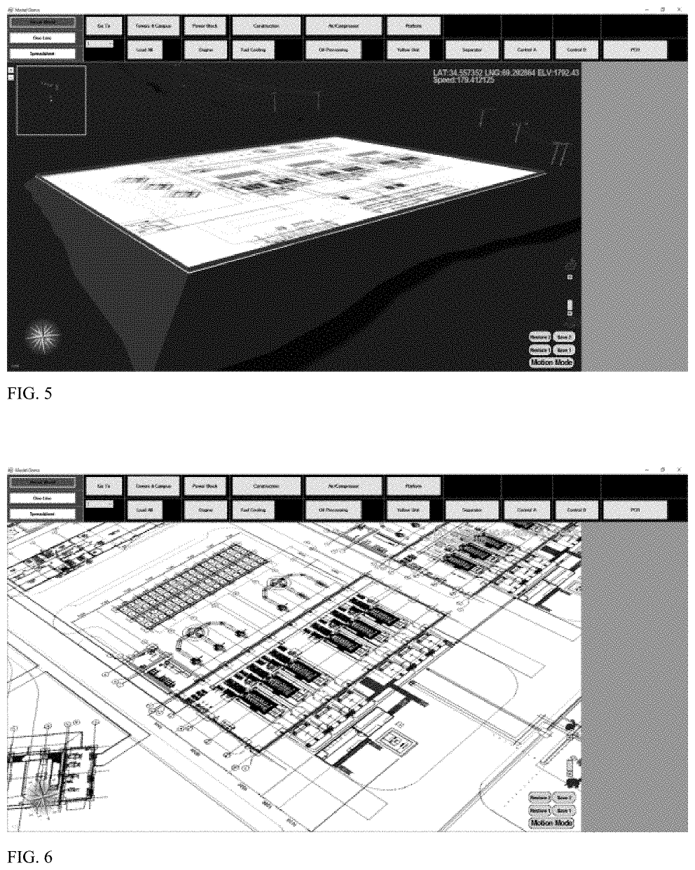

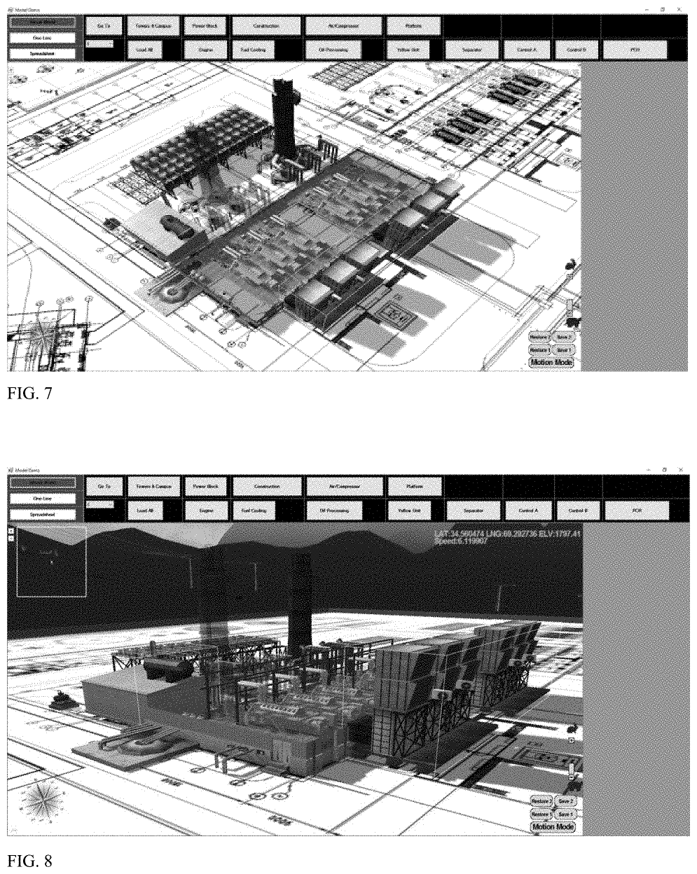

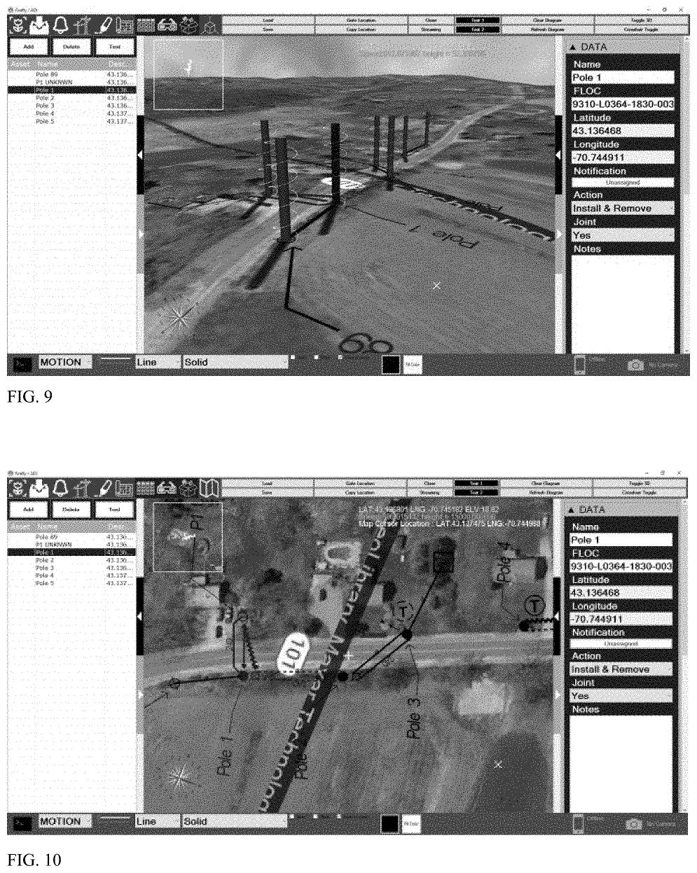

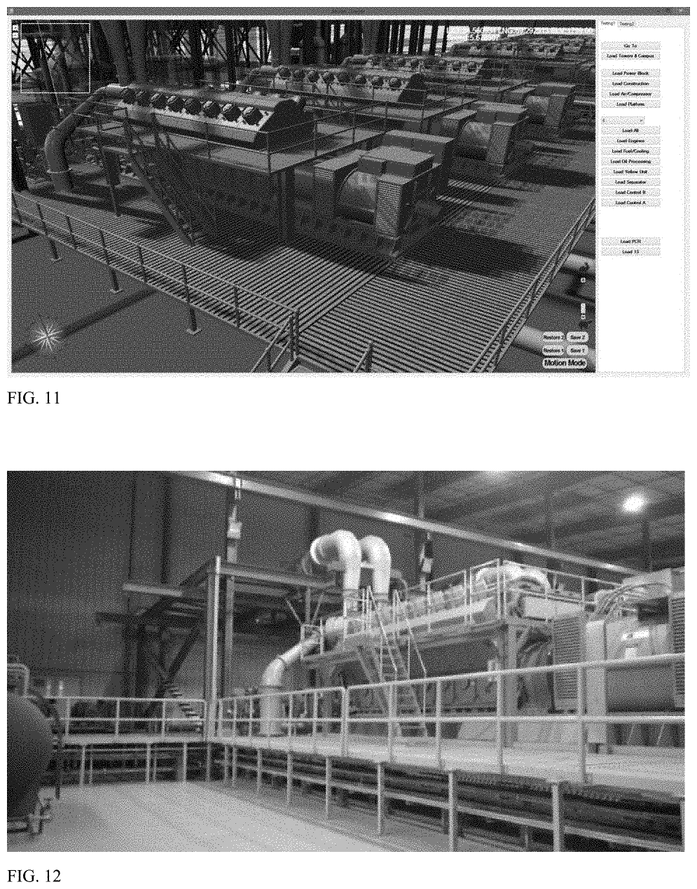

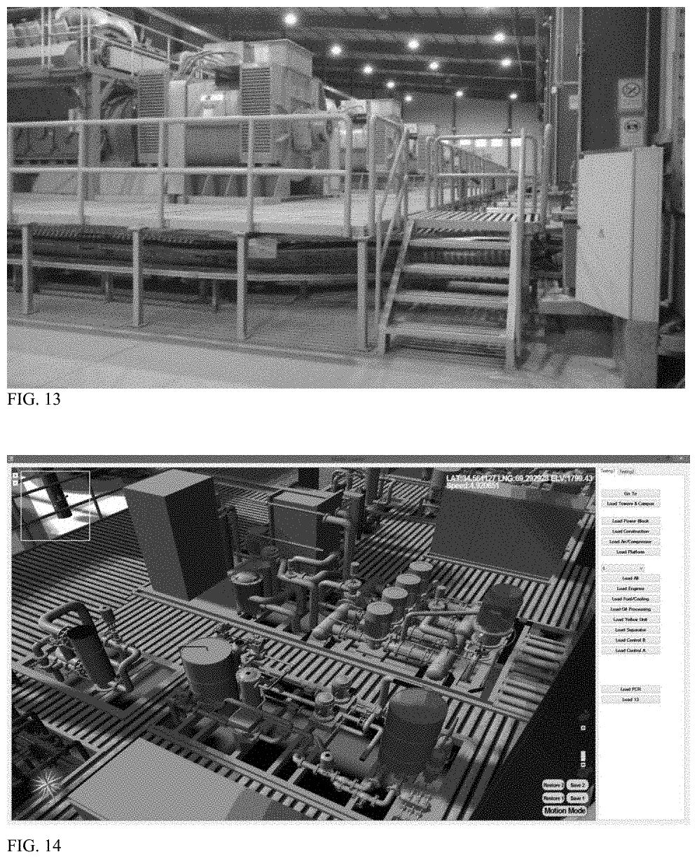

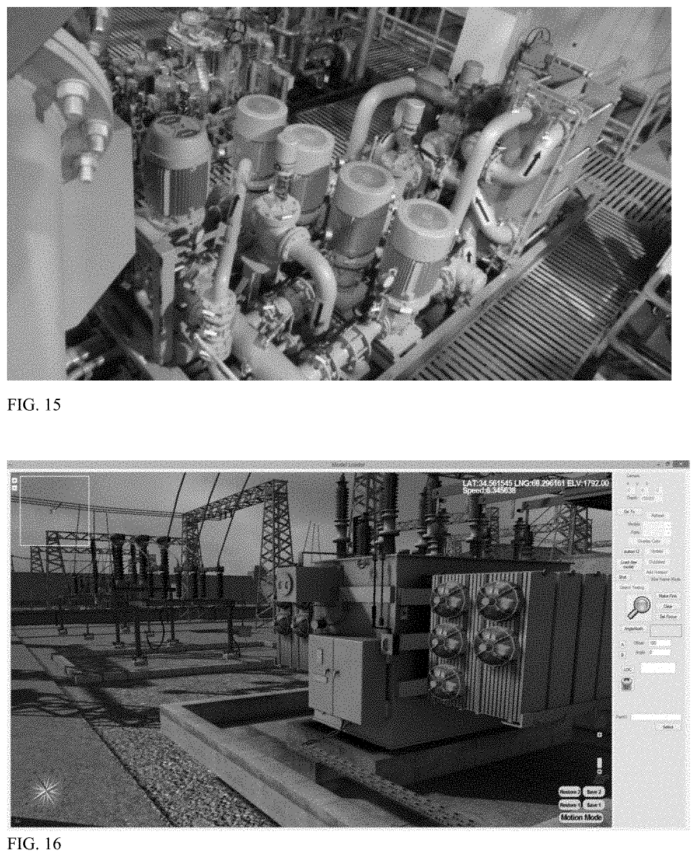

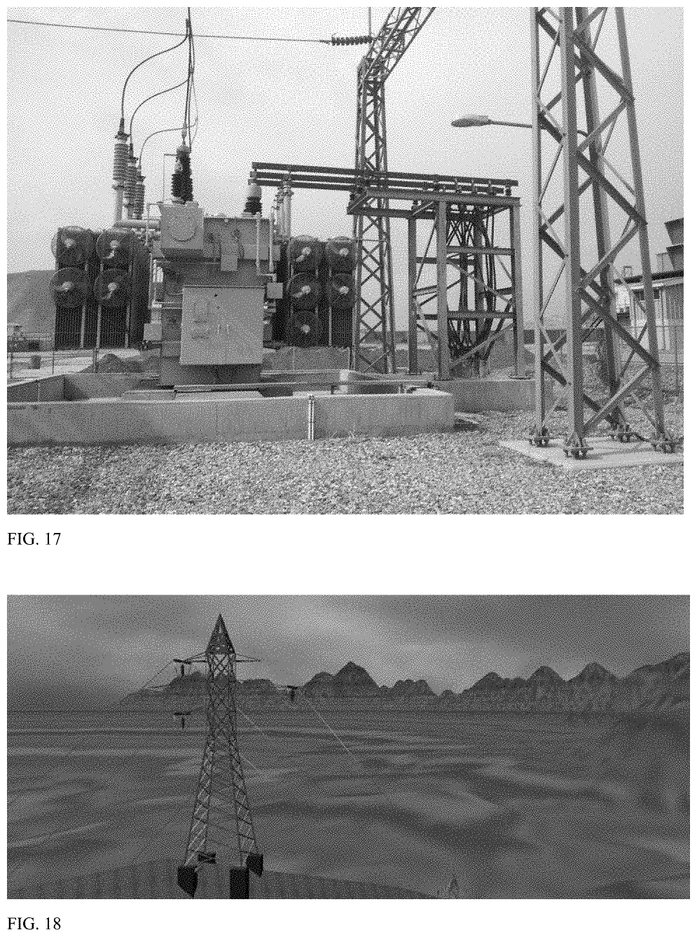

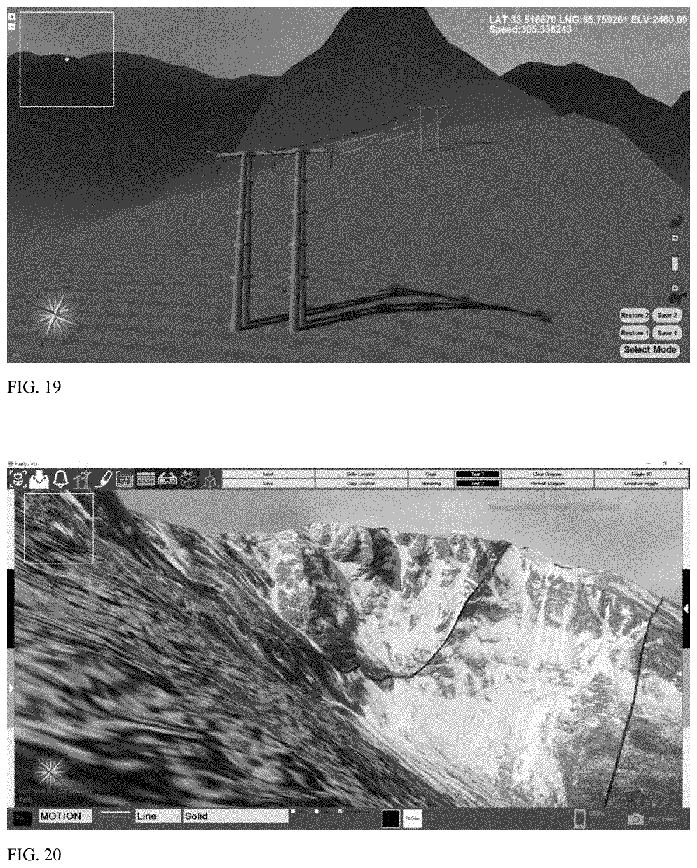

As shown in FIGS. 5-10, infrastructure including utility assets may be modeling can be in either 2D, 3D, or a combination of both and mixed together. A 2D one-line diagram of a power plant may be laid over the ground in its real-world physical location based on GPS coordinates. Accurate terrain may be modeled. A 3D model of the modeled power plant may be viewed on top of the blueprint, which is dimensionally accurate. In a view, electric poles in a distribution system may be shown with circuit construction diagrams drawn directly onto the modeled terrain.

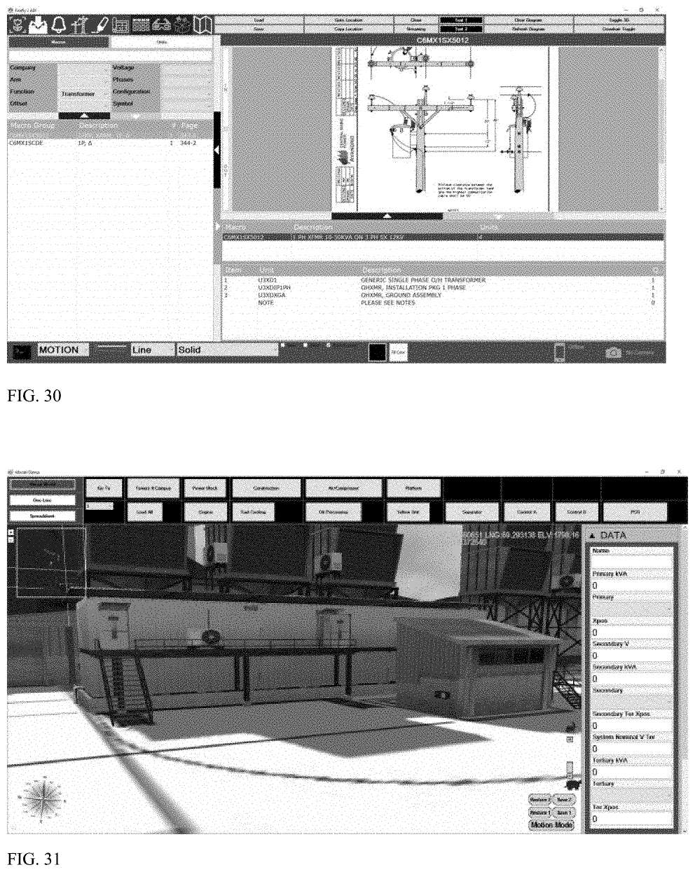

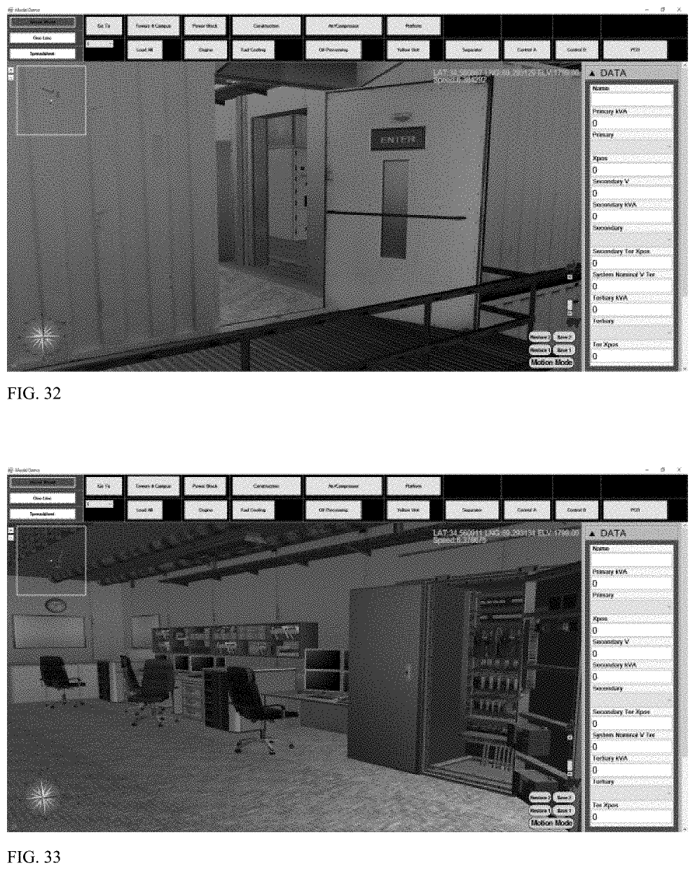

In an embodiment, an infrastructure model may include utility asset management capabilities enabled in the navigable virtual environment. A user may walk around in a generation plant, switchyard, substation, or along a transmission line in the virtual environment. As shown in FIG. 30, in an embodiment, utility asset information may include asset data such as asset specifications or instructions for performing maintenance or repairs on damaged assets. In an embodiment utility asset information may include data sheets from the manufacturer. In an embodiment, infrastructure model image information and utility asset image information may include information and capability to perform engineering calculations based on photos, including tools that allow 2D photos to be analyzed for the purpose of measuring data of utility assets, such as the height of a transmission tower calculated in relation to a known or designated reference point, or a reference object of known dimensions, in the photo.

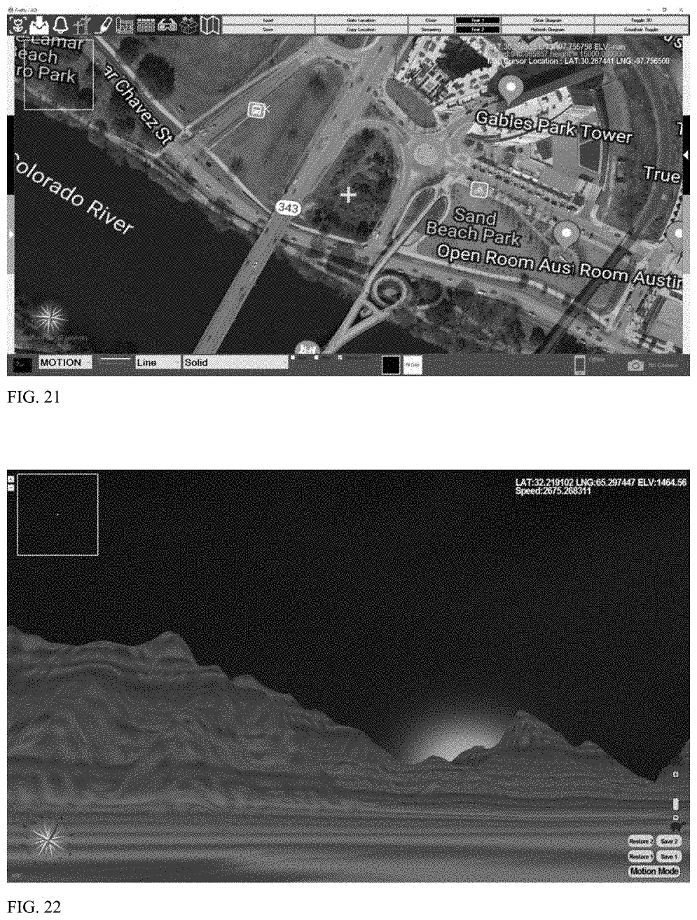

In an embodiment, in order to perform inspections with collection of power line imaging data, such as lidar data, the disclosed subject matter may visualize a point cloud in the context of the surrounding environment. Disclosed subject matter may incorporate any of the following features. An embodiment may provide a precise and realistic geospatial virtualization of the earth, such as by incorporating GPS coordinates, terrain information, and mapping information. In an embodiment, a virtual world may be visualized in terms of geospatial coordinates, specifically GPS coordinates. The ground may be realistically modeled and earth elevation data obtained and integrated into the application, and used to model the terrain. FIG. 19 shows use of a heat haze to colorize the ground based on elevation. FIGS. 20-21 show, for example, the use of satellite imagery data to texturize the ground. Lidar data also may be seen in the context of map data. In an embodiment, the virtual environment may accurately visualize lidar data within a GPS-accurate virtual world, relative to and correctly aligned with the terrain and mapping data. In an embodiment, transmission and distribution infrastructure, such as transmission towers and conductors may be modeled to be compared to collected lidar data. Lidar data may be stored in horizontally expansive cloud database for efficient retrieval in relation to a coordinate-based search index.

The virtual world may geodetically model planet earth. In an embodiment, the virtual world, in addition to modelling data provided to the virtual world platform, may simulate and generate data. In an embodiment, for example, objects placed in the world based on geodetic definitions may be manipulated by the user inside the game engine. In such case the objects' coordinate definitions will change, and consequently the real-world GPS definitions will be reflected. In such cases the virtual world, which is a simulation, may become the source of truth for this information.

In an embodiment, the virtual world platform may accurately visualize power line imaging data, such as lidar data, within the GPS-accurate virtual world, relative to and correctly aligned with terrain and mapping data. Lidar cloud points may be rendered as sprites, which are two dimensional bitmaps. Terrain mapping may enable manual review of collected lidar data, and may enable replicating collection of power line imaging data by simulated flight along the power line route, or enable simulation of field visual inspection such as walking down the power line route in the virtual world, and enable the viewer to visually assess damage by viewing the infrastructure model including a plurality of utility asset models in the virtual environment generated by the virtual world platform.

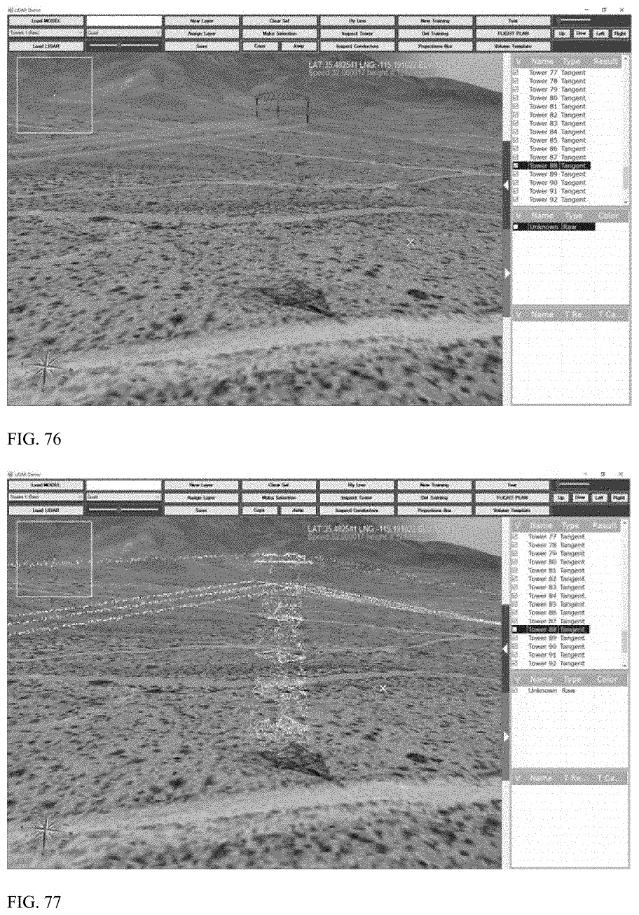

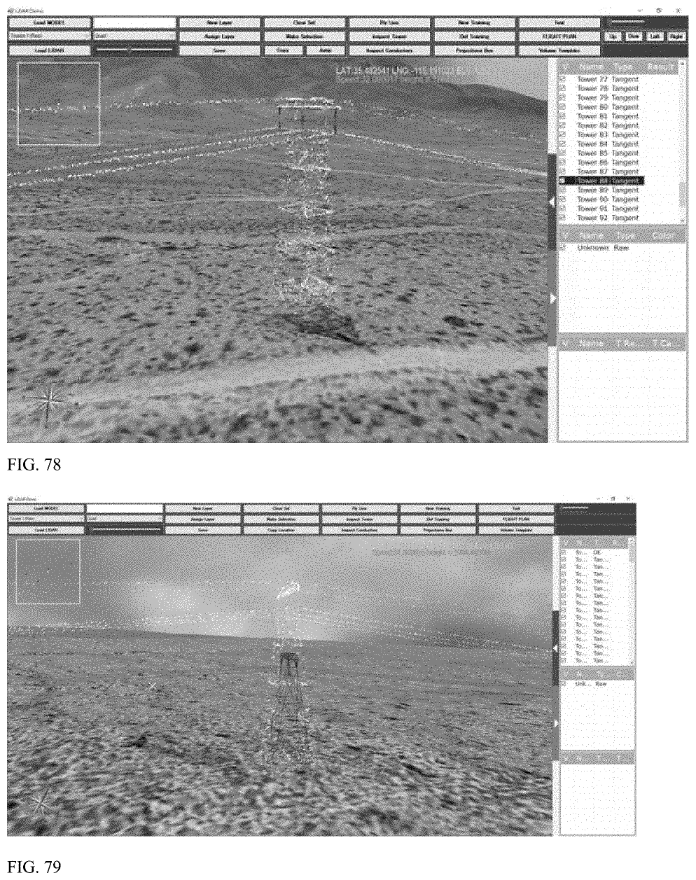

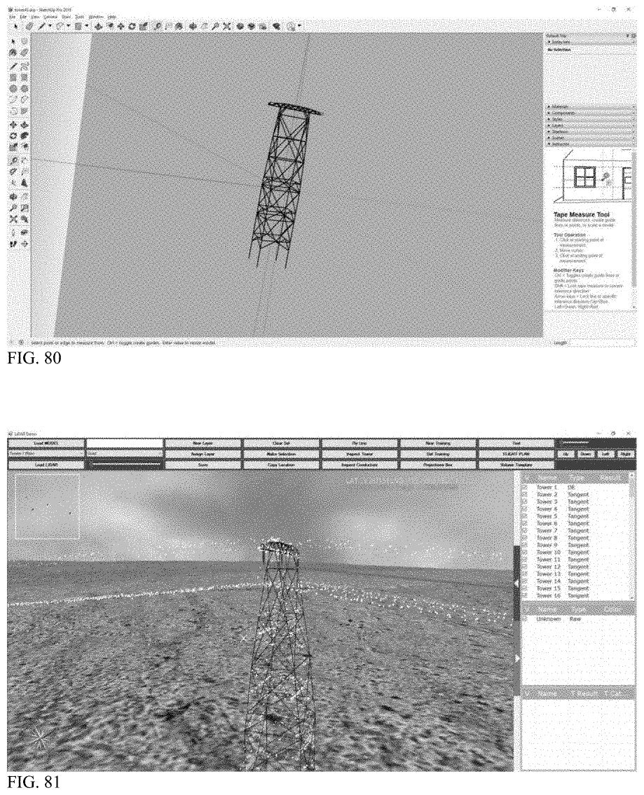

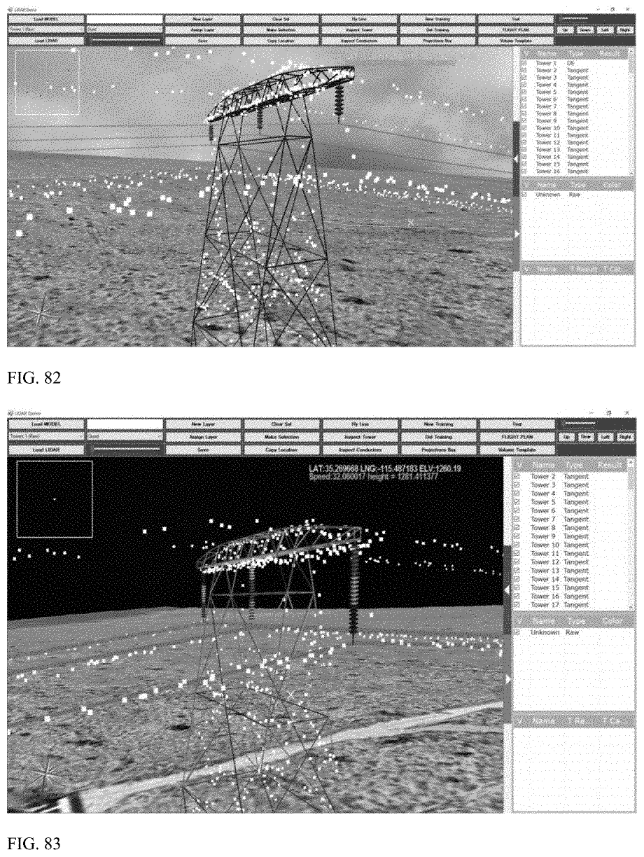

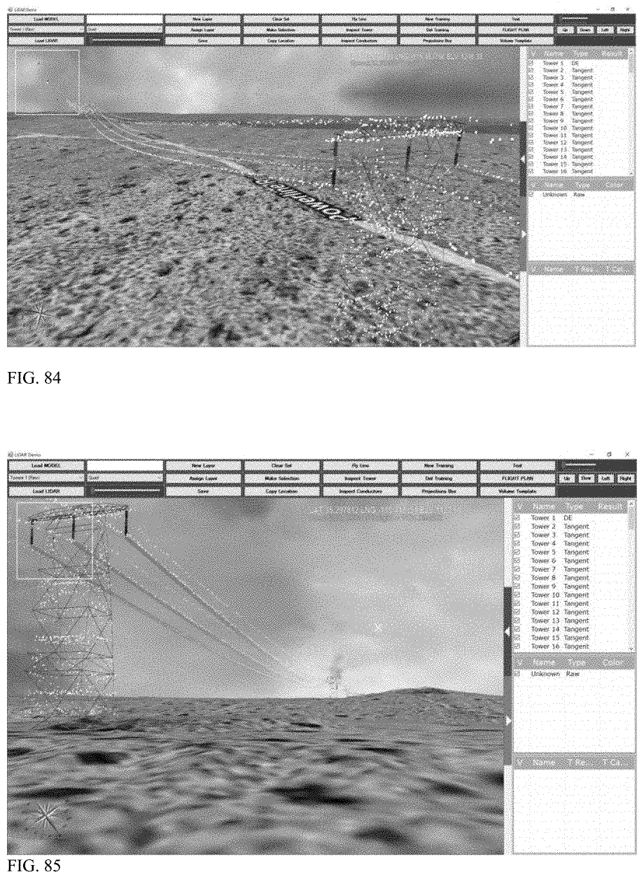

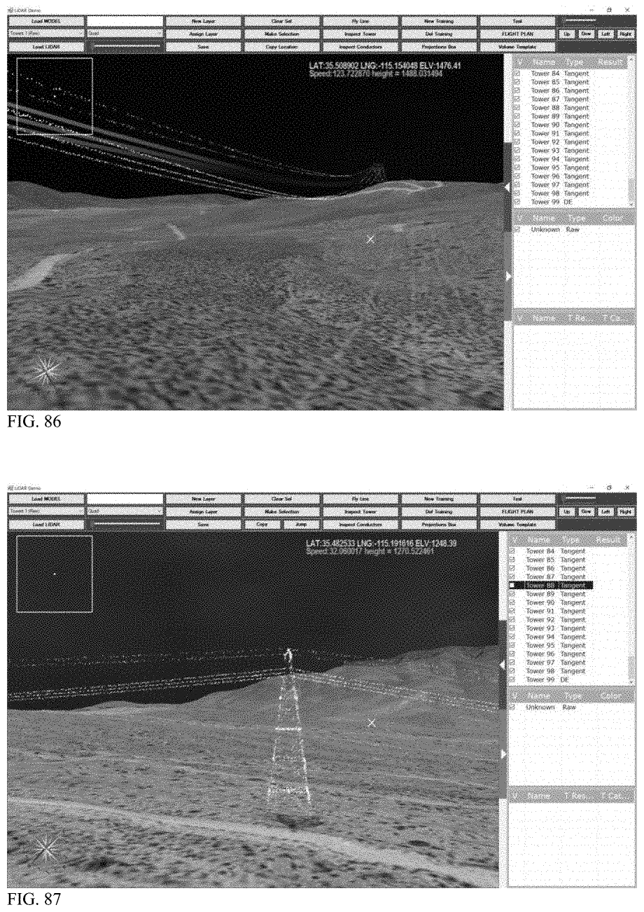

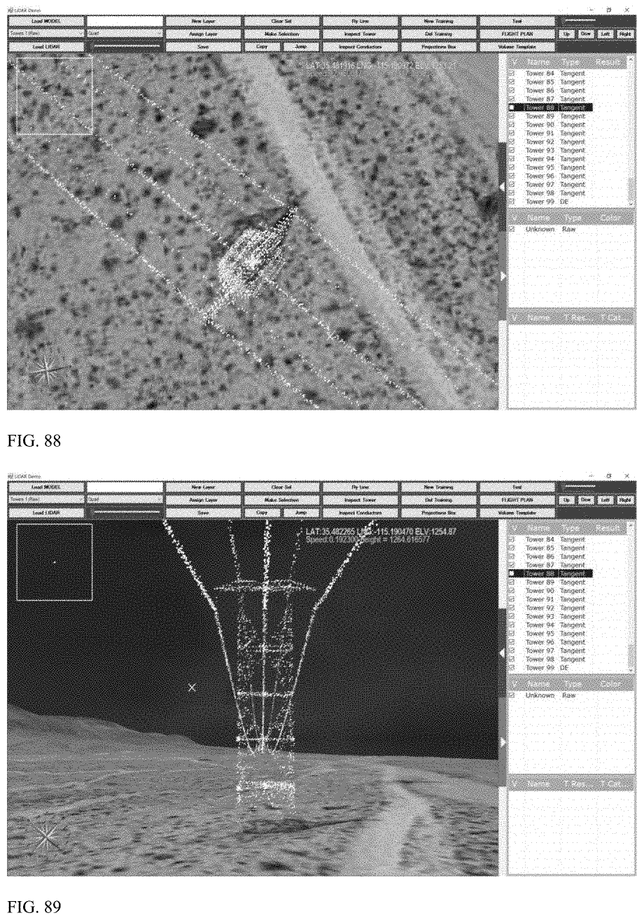

Lidar data may be independent from utility asset data, where the two are not directly linked in any way. In an embodiment, therefore, these are visualized in the virtual world independently. FIG. 77 shows a visualization of the FC2 lidar data from the same position and perspective used in FIG. 76, looking towards tower 88. FIG. 78 shows four of data sources combined: lidar plus asset model, along with terrain and mapping.

In an embodiment, positions of utility assets such as transmission towers may be treated as waypoints, between which tracks are laid. Tracks may be calibrated according to flight parameters such as travel speed and the distance in meters represented by track, which varies both by span length and geodetic coordinate translation. A per track delay is determined and then subsequently imposed by a timekeeper.

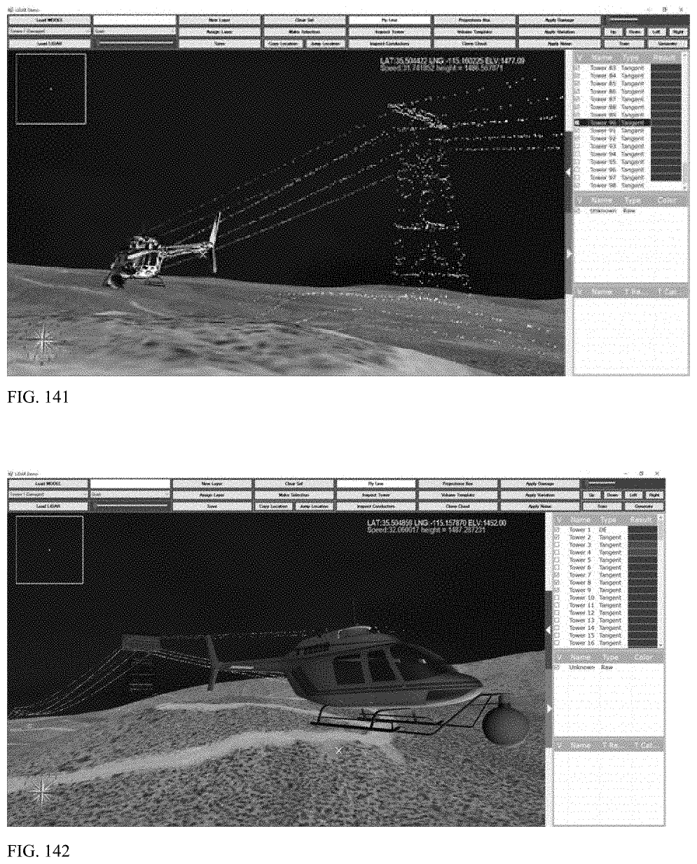

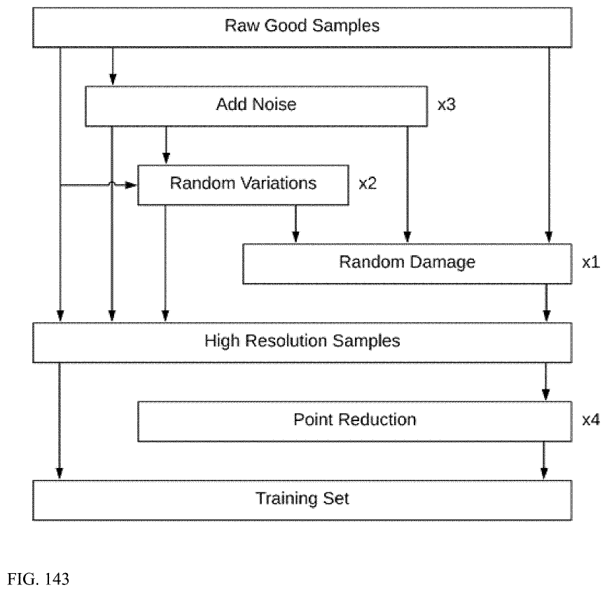

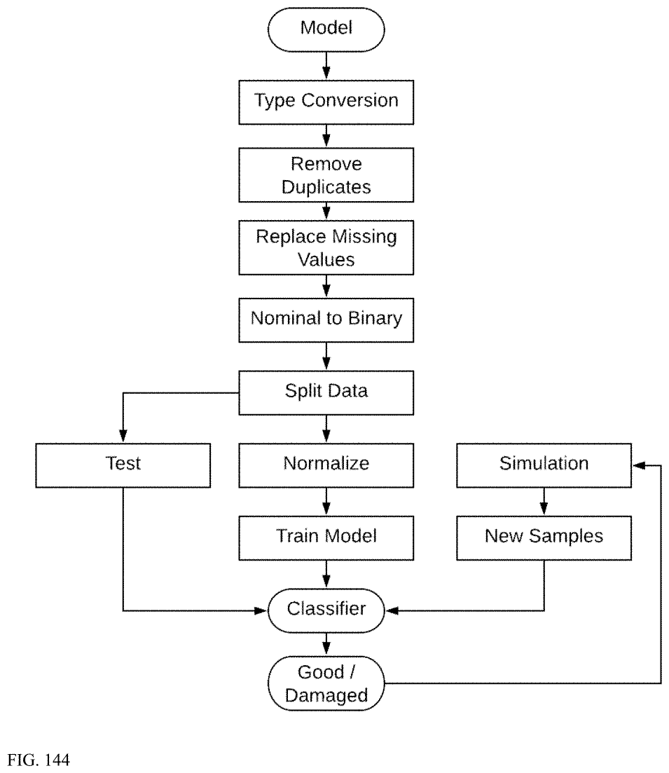

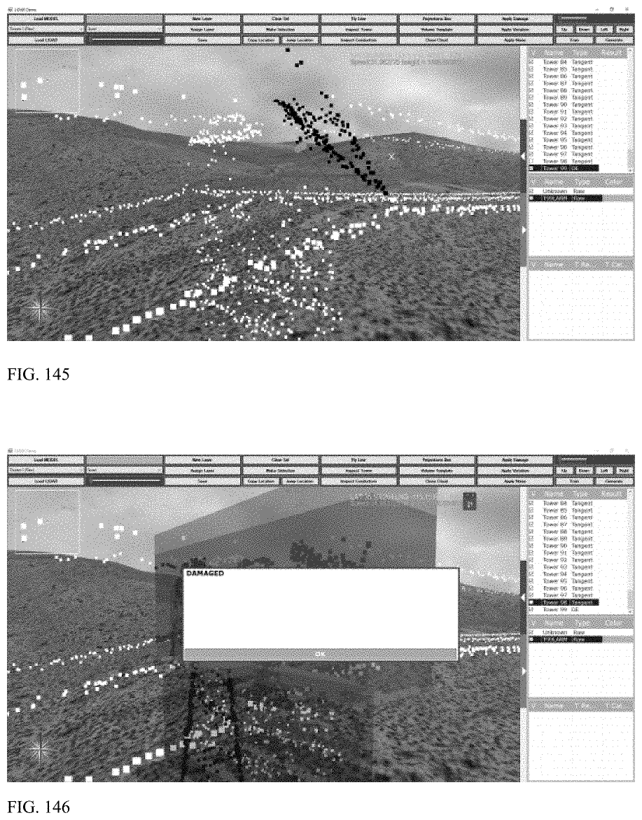

In each track iteration lidar data pertaining to the region encompassed by the track may be streamed from the indexed set of lidar data. The virtual world platform may then take over, visualizing the data and passing it off to be processed for acquisition and classification. As shown in FIG. 141, in a simulation, as lidar data is being visualized, simultaneously, flight of a model of a helicopter along the same collection route may precisely simulate collection of the lidar data. As the virtual helicopter flies, and data is streamed in, the lidar point data materializes in the virtual environment. As the flight simulation is running, the user is able to walk around in the virtual environment freely and interact with the data. The asset model may be shown or hidden. The simulation may also be paused and then resumed. FIG. 143 depicts how shortly after the helicopter departs from having passed over an area of interest, a volume template is loaded to perform an acquisition in that target area, the results of which will then be passed off to feature extraction and the classifier.

Apparatus, methods and systems according to embodiments of the disclosure are described. Although specific embodiments are illustrated and described herein, it will be appreciated by those of ordinary skill in the art that any arrangement which is calculated to achieve the same purposes can be substituted for the specific embodiments shown. This application is intended to cover any adaptations or variations of the embodiments and disclosure. For example, although described in terminology and terms common to the field of art, exemplary embodiments, systems, methods and apparatus described herein, one of ordinary skill in the art will appreciate that implementations can be made for other fields of art, systems, apparatus or methods that provide the required functions. The invention should therefore not be limited by the above-described embodiments, methods, and examples, but by all embodiments and methods within the scope and spirit of the invention.

In particular, one of ordinary skill in the art will readily appreciate that the names of the methods and apparatus are not intended to limit embodiments or the disclosure. Furthermore, additional methods, steps, and apparatus can be added to the components, functions can be rearranged among the components, and new components to correspond to future enhancements and physical devices used in embodiments can be introduced without departing from the scope of embodiments and the disclosure. One of skill in the art will readily recognize that embodiments are applicable to future systems, future apparatus, future methods, and different materials.

All methods described herein can be performed in a suitable order unless otherwise indicated herein or otherwise clearly contradicted by context. The use of any and all examples, or exemplary language (e.g., “such as”), is intended merely to better illustrate the disclosure and does not pose a limitation on the scope of the disclosure unless otherwise claimed. No language in the specification should be construed as indicating any non-claimed element as essential to the practice of the disclosure as used herein. Terminology used in the present disclosure is intended to include all environments and alternate technologies that provide the same functionality described herein.

1. A method for managing an electric utility power transmission and distribution grid, said grid including a plurality of utility assets distributed on a utility power line route in a geographic area, said method comprising:
receiving, at a processor, infrastructure information of said grid including said plurality of utility assets distributed on said utility power line route in said geographic area;
generating, by a processor, an infrastructure model of said grid, said infrastructure model comprising utility asset data objects in relation to said plurality of utility assets, said infrastructure model comprising asset classification data in relation to said plurality of utility asset data objects, said infrastructure model comprising infrastructure model image information;
receiving, at a processor, power line imaging data collected along said power line route, said power line imaging data comprising utility asset imaging data in relation to said plurality of utility assets;
receiving, at a processor, geospatial topological model information for said geographic area, said geospatial topological model information comprising terrain data and elevation data, said geospatial topological model information comprising geospatial topological model image information;
generating, by a processor of a virtual world platform, a simulated virtual environment model comprising an integration of said power line imaging data in relation to said geospatial topological model information in relation to said infrastructure model, said integrated model comprising integrated image information, said integrated image information comprising an integrated visualization of said infrastructure model image information with said geospatial topological model image information and with said power line imaging data.

2. A method according to claim 1, said method further comprising:
rendering, by a processor, a navigable virtual environment comprising said integrated image information comprising said integrated visualization.

3. A method according to claim 2, said method further comprising:
generating, by a processor, a viewer in relation to said navigable virtual environment, said viewer comprising a point of view, said viewer comprising for said point of view a virtual view on said utility power line route depicted in said navigable virtual environment.

4. A method according to claim 3, said method further comprising:
said virtual view comprising said integrated visualization, said integrated visualization comprising said infrastructure model image information comprising utility asset image information for said plurality of utility assets.

5. A method according to claim 3, said method further comprising:
outputting, by a processor, said virtual view to a display.

6. A method according to claim 4, said method further comprising:
navigating, by a processor, said viewer in relation to said navigable virtual environment, said navigating of said viewer providing a plurality of virtual views on said utility power line route depicted in said navigable virtual environment, said plurality of virtual views comprising said integrated visualization comprising said infrastructure model comprising utility asset image information for said plurality of utility assets.

7. A method according to claim 6, said method further comprising:
simulating, by a processor, navigation of said viewer in relation to said navigable virtual environment to provide a simulated time series for a plurality of camera points of view a corresponding simulated time series of a plurality of virtual views on said utility power line route depicted in said navigable virtual environment, said plurality of virtual views comprising said integrated visualization comprising said infrastructure model comprising utility asset image information for said plurality of utility assets.

8. A method according to claim 6, said method further comprising:
receiving, at a processor, said plurality of virtual views from said viewer;
examining, by a processor, said plurality of virtual views to identify damage visible in said integrated visualization comprising said infrastructure model image information comprising utility asset image information for said plurality of utility assets.

9. A method according to claim 4, said method further comprising:
classifying, by a processor, utility assets in said virtual view as being in normal condition or damaged condition, by performing a trained classification algorithm in run-time mode to compare said collected power line imaging data to reference classification information, said trained classification algorithm in a training period developing said reference classification information in relation to receiving reference power line imaging data for a plurality of utility assets classified in known normal condition or damaged condition.

10. A method according to claim 9, said method further comprising:
said trained classification algorithm in said training period developing said reference classification information in relation to receiving said reference power line imaging data in a reference view of infrastructure comprising a utility asset, said reference view selected from: a virtual view, a real-world image, or both.

11. A method according to claim 1, said method further comprising:
said power line imaging data comprising lidar data.

12. A method according to claim 11, said method further comprising:
said power line imaging data comprising telemetry data.

13. A method according to claim 1, said method further comprising:
said power line imaging data selected from the following:
lidar data, telemetry data, photography data, and photogrammetry data.

14. A method according to claim 9, said method further comprising:
said integrated model comprising first geographic location information having first resolution for said geospatial topological model, second geographic location information having second resolution for said infrastructure model in relation to said first geographic location information, and third geographic location information having third resolution for said power line imaging data in relation to at least one of the following: said first geographic location information and said second geographic location information; said first resolution, second resolution and third resolution sufficient to enable said classifying of utility assets in said virtual view as being in normal condition or damaged condition by reference to said integrated model.

15. A method according to claim 14, said method further comprising:
said first resolution, second resolution and third resolution sufficient to enable said classifying by said trained classification algorithm of utility assets in said virtual view as being in normal condition or damaged condition by reference to said integrated model without receiving first-person field storm damage survey information for condition of each of said plurality of utility assets on said power line route.

16. A method according to claim 15, said method further comprising:
said classifying by said trained classification algorithm of utility assets in said virtual view as being in normal condition or damaged condition by reference to said integrated model providing a level of assessment precision substantially equal to first-person field storm damage survey information for visual field assessment of condition of each of said plurality of utility assets on said power line route.

17. A method according to claim 15, said method further comprising:
said classifying by said trained classification algorithm of utility assets in said virtual view as being in normal condition or damaged condition by reference to said integrated model providing a level of assessment precision sufficient to enable automated dispatching assignments of storm damage repair crews with service equipment and substantially identical replacement utility assets sufficient to restore damaged infrastructure to substantially normal condition for said plurality of utility assets on said power line route at automated utilization efficiency substantially equal to field survey utilization efficiency of manual dispatching assignments enabled by first-person storm damage field survey information for said plurality of utility assets on said power line route.

18. A method according to claim 14, said method further comprising:
said classifying by said trained classification algorithm of utility assets in said virtual view as being in normal condition or damaged condition by reference to said integrated model providing information sufficient to dispatch field survey personnel to perform first-person storm damage field surveys to perform field assessments of condition of each of said plurality of utility assets on said power line route classified in an indeterminate condition by said trained classification algorithm.

19. A method according to claim 1, said method further comprising:
in said receiving, said power line imaging data stored in a cloud database indexed by geospatial information.

20.-60. (canceled)

61. A non-transitory computer-accessible medium having stored thereon computer-executable instructions for managing an electric utility power transmission and distribution grid, wherein, when a computer hardware arrangement executes the instructions, the computer hardware arrangement is configured to perform procedures comprising the method of claim 1.
